(19) United States
(12) Patent Application Publication
(10) Pub. No.: US 2026/0186607 A1
(43) Pub. Date: Jul. 2, 2026

(54) Display Device

(71) Applicant: LG Display Co., Ltd., Seoul (KR)

(72) Inventors: Ruda Rhe, Paju-si (KR); JiHyun Jung, Paju-si (KR); Hyangmyoung Gwon, Paju-si (KR)

(21) Appl. No.: 19/220,006

(22) Filed: May 27, 2025

(30) Foreign Application Priority Data
Dec. 27, 2024 (KR) 10-2024-0198536

(51) Int. Cl. G06F 3/044; G06F 3/041; H10H 29/855

(52) U.S. Cl. CPC G06F 3/0443; G06F 3/04164; H10H 29/8552

(57) ABSTRACT

A display device is disclosed. The display device includes a cathode and a first touch electrode that are disposed on the first light emitting device and the second light emitting device. The cathode and the first touch electrode are disposed on the same layer and are spaced apart from each other.

### CROSS-REFERENCE TO RELATED APPLICATION

This application claims the benefit of the Republic of Korea Patent Application No. 10-2024-0198536 filed on Dec. 27, 2024, which is hereby incorporated by reference in its entirety.

### BACKGROUND

### Field of Technology

The present disclosure relates to a display device.

### Description of the Related Art

The display device is applied to various electronic devices such as televisions (TVs), mobile phones, laptops, and tablets.

The display devices include an organic light emitting display (OLED) that emit light by themselves and a liquid crystal display (LCD) that require a separate light source.

Recently, a display device including a light emitting diode (LED) has attracted attention as a next-generation display device. The light emitting diode is made of an inorganic material rather than an organic material. Accordingly, compared to the liquid crystal display or the organic light emitting display device, the display device including the light emitting diode has a faster lighting speed, excellent luminous efficiency, and displays an image having high luminance.

In addition, research is being conducted to simplify the manufacturing process of the display device.

### SUMMARY

The present disclosure has been made in view of the above problems and it is an embodiment of the present disclosure to provide a display device that simplifies a manufacturing process, optimizes the manufacturing process, and reduces production energy.

In addition, the present disclosure has been made in view of the above problems and it is an embodiment of the present disclosure to provide a display device with a reduced thickness.

In accordance with an embodiment of the present disclosure, the above and other technical effects can be accomplished by the provision of a display device comprising a plurality of pixels disposed on a substrate, a first sub-pixel and a second sub-pixel disposed in the plurality of pixels and spaced apart from each other, a first light emitting device disposed in the first sub-pixel, a second light emitting device disposed in the second sub-pixel, and a cathode and a first touch electrode disposed on the first light emitting device and the second light emitting device, wherein the cathode and the first touch electrode are disposed on the same layer and are spaced apart from each other.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is an exploded perspective view of a display device according to an embodiment of the present disclosure.

FIG. 2 is a plan view of a display device according to an embodiment of the present disclosure.

FIG. 3 is an enlarged view of a display device according to an embodiment of the present disclosure.

FIG. 4 is a diagram illustrating a circuit of a pixel according to an embodiment of the present disclosure.

FIG. 5 is a plan view of a first display area of a display device according to an embodiment of the present disclosure.

FIG. 6 is an enlarged view of an area A of FIG. 5 according to an embodiment of the present disclosure.

FIG. 7 is a plan view of a display area of a display device according to an embodiment of the present disclosure.

FIG. 8 is a plan view of a display area of a display device according to an embodiment of the present disclosure.

FIG. 9 is a plan view of a display area of a display device according to a first embodiment of the present disclosure.

FIG. 10 is a cross-sectional view of a display device according to a first embodiment of the present disclosure.

FIG. 11 is a cross-sectional view of a first light emitting device according to an embodiment of the present disclosure.

FIG. 12 is a plan view of a display area of a display device according to a second embodiment of the present disclosure.

FIG. 13 is a plan view of a display area of a display device according to a third embodiment of the present disclosure.

FIG. 14 is a cross-sectional view of a display device according to a second embodiment and a third embodiment of the present disclosure.

FIG. 15 is a configuration diagram of a wiring of a display device according to an embodiment of the present disclosure.

FIG. 16 is a block diagram of a Tx electrode according to a first embodiment of the present disclosure.

FIG. 17 is a block diagram of a Tx electrode according to a second embodiment of the present disclosure.

FIG. 18 is a block diagram of a Tx electrode according to a third embodiment of the present disclosure.

FIG. 19 is a plan view of a display device according to another embodiment of the present disclosure.

FIG. 20 is an enlarged view of a partial area of FIG. 19 according to an embodiment of the present disclosure.

FIG. 21 is a cross-sectional view of a display device according to an embodiment of the present disclosure.

FIG. 22 is a plane diagram of a display device according to another embodiment of the present disclosure.

FIG. 23 is a block diagram of a touch electrode according to a first embodiment of the present disclosure.

FIG. 24 is a block diagram of a touch electrode according to a second embodiment of the present disclosure.

FIG. 25 is a block diagram of a touch electrode according to a third embodiment of the present disclosure.

FIG. 26 is a cross-sectional view of a display device according to another embodiment of the present specification.

FIG. 27 is a cross-sectional view of a display device according to another embodiment of the present specification.

FIGS. 28 to 31 are diagrams illustrating devices to which a display device according to embodiments of the present disclosure is applied.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example. However, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise', 'have’ and ‘include’ described in the present disclosure are used, another portion may be added unless ‘only˜’ is used. The terms of a singular form may include plural forms unless referred to the contrary.

The word “exemplary” is used to mean serving as an example or illustration. Aspects are example aspects. “Embodiments,” “examples,” “aspects,” and the like should not be construed as preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In construing an element, the element is construed as including an error band although there is no explicit description. Any implementation described herein as an “example” is not necessarily to be construed as preferred or advantageous over other implementations.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used. The terms, such as “below,” “lower,” “above,” “upper” and the like, may be used herein to describe a relationship between element(s) as illustrated in the drawings. It will be understood that the terms are spatially relative and based on the orientation depicted in the drawings.

It will be understood that, although the terms “first,” “second,” “A,” “B,”“(a),” and “(b)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, one embodiment of the present disclosure will be described in detail with reference to the accompanying drawings.

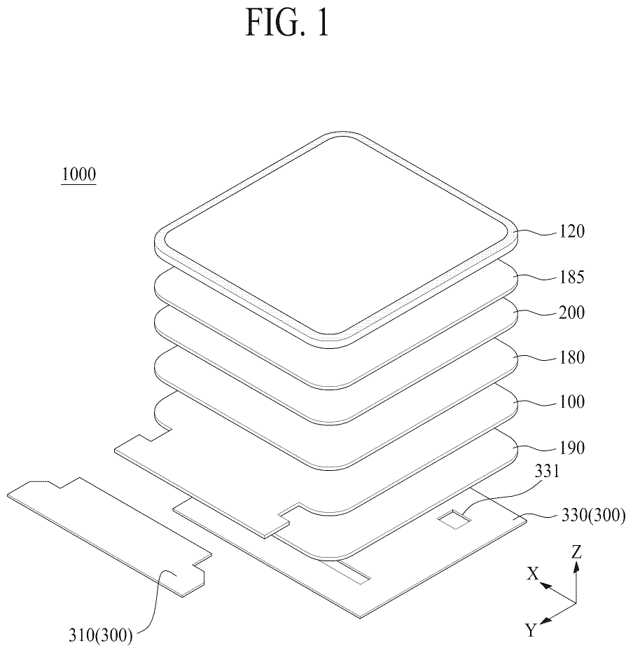

FIG. 1 is an exploded perspective view of a display device according to an embodiment of the present disclosure.

Referring to FIG. 1, a display device 1000 according to an embodiment of the present disclosure may include a display panel 100, a cover member 120, a polarizing layer 180, an adhesive layer 185, a support substrate 190, and a driving circuit unit 300.

The display panel 100 may implement information, a video, and/or an image provided to a user. Also, the display panel 100 may sense a user's touch. The cover member 120 is disposed on the display panel 100 and may protect the display panel 100. The polarizing layer 180 may be disposed between the display panel 100 and the cover member 120. The polarizing layer 180 may prevent or reduce light generated from an external light source from entering the display panel 100 and affecting a light emitting device or the like. The adhesive layer 185 may be disposed between the polarizing layer 180 and the cover member 120 and may attach the cover member 120 to the polarizing layer 180. The support substrate 190 may be disposed on a rear surface of the display panel 100. The support substrate 190 may reinforce rigidity of the display panel 100.

The driving circuit unit 300 may be electrically connected to the display panel 100. The driving circuit unit 300 may generate a signal required to display an image on the display panel 100 and supply the signal to the display panel 100. The driving circuit unit 300 may include a flexible circuit board 310 and a printed circuit board 330.

The flexible circuit board 310 and the printed circuit board 330 may be disposed on a bottom of the display panel 100. The flexible circuit board 310 and the printed circuit board 330 may be disposed on a rear surface of the support substrate 190. One side of the flexible circuit board 310 may be attached to the display panel 100, and the other side of the flexible circuit board 310 may be attached to the printed circuit board 330, but is not limited thereto. The printed circuit board 330 may include at least one hole 331. An internal component may be disposed in an area corresponding to the at least one hole 331. The internal component may include an ambient light sensor (ALS) or a temperature sensor, but is not limited thereto.

The display device 1000 according to an embodiment of the present disclosure may further include an insulating layer 200. The insulating layer 200 may be disposed between the display panel 100 and the cover member 120. For example, the insulating layer 200 may be disposed between the cover member 120 and polarizing layer 180. The insulating layer 200 may be connected to or attached to a rear surface of the cover member 120 by a transparent adhesive member.

The insulating layer 200 may include a touch electrode layer having a touch electrode for sensing a user's finger touch or a pen touch on the display panel 100. The touch electrode layer may sense a change in capacitance of the touch electrode according to a user's touch.

The driving circuit unit 300 may be electrically connected to the touch electrode of the insulating layer 200. The driving circuit unit 300 may sense a change in capacitance of the touch electrode of the insulating layer 200. And, the driving circuit unit 300 may generate touch coordinate data corresponding to a user's touch position and may provide the touch coordinate data to a host control unit.

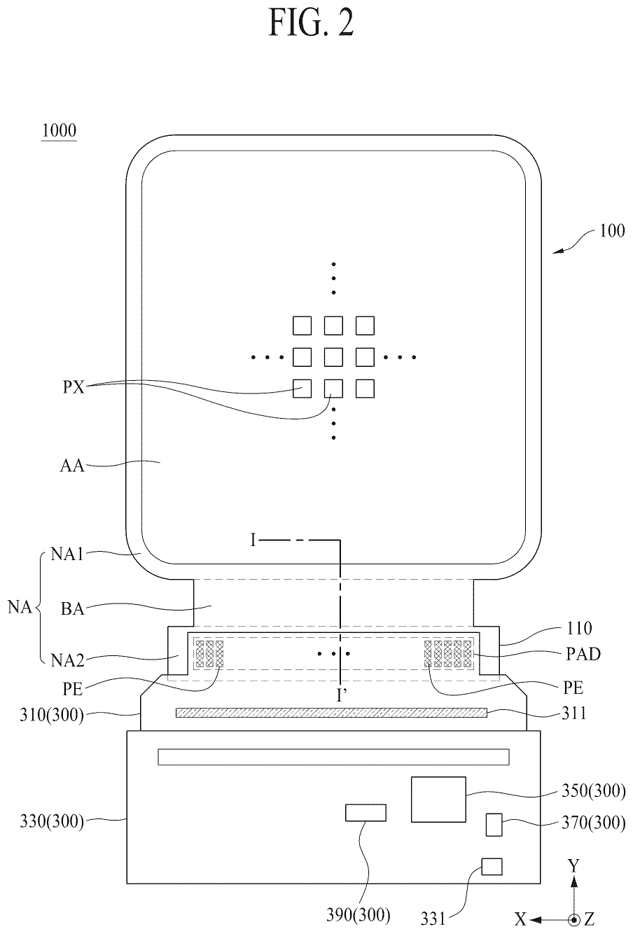

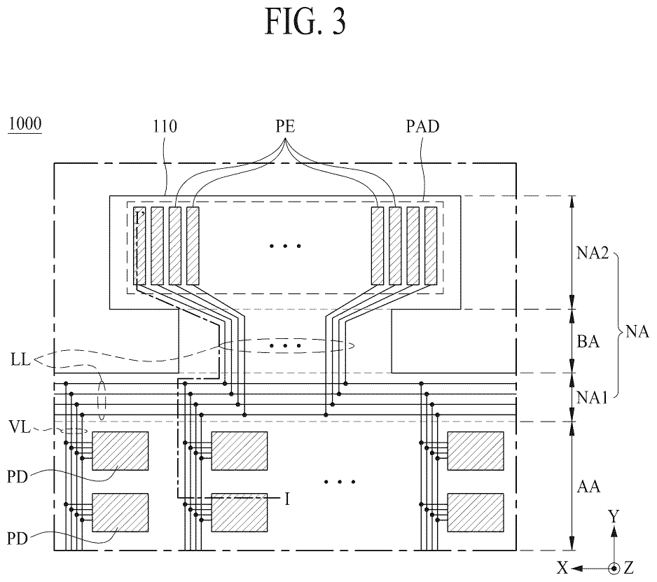

FIG. 2 is a plan view of a display device according to an embodiment of the present disclosure. FIG. 3 is an enlarged view of a display device according to an embodiment of the present disclosure.

Referring to FIGS. 2 and 3, the display device 1000 may include the display panel 100, the flexible circuit board 310, and the printed circuit board 330.

The display panel 100 may include a substrate 110. The substrate 110 may be made of an insulating material such as glass or resin. Also, the substrate 110 may be made of a material having flexibility such as polyimide (PI).

The display panel 100 may include a display area AA and a non-display area NA. For example, the substrate 110 may include the display area AA and the non-display area NA. The display area AA and the non-display area NA are not limited to the substrate 110 but may be described throughout the display device 1000.

The display area AA may be an area in which an image is displayed. The display area AA may include a plurality of pixels PX. Each of the plurality of pixels PX may include a plurality of sub-pixels, and each of the plurality of sub-pixels may include a plurality of light emitting devices.

The plurality of light emitting devices and the photo detector may be configured to be different according to a type of the display device 1000. For example, when the display device 1000 is an inorganic light emitting display device, the light emitting device may be a light-emitting diode (LED), a micro light-emitting diode (Micro-LED), or a mini-light-emitting diode (MLED), but embodiments of the present disclosure are not limited thereto.

Referring to FIG. 3, a plurality of pixel driving circuits PD may be disposed in the display area AA. The plurality of pixel driving circuits PD may be disposed in each of the plurality of pixels PX.

In the plurality of pixels PX, the plurality of pixel driving circuits PD may be circuits for driving light emitting devices of the plurality of sub-pixels. That is, each of the plurality of pixel driving circuits PD may control a light emitting operation of the plurality of light emitting devices. In addition, each of the plurality of pixel driving circuits PD is a microchip or chipset and may be a semiconductor packaging device with a fine size including a plurality of transistors and storage capacitors.

The non-display area NA may be an area in which no image is displayed. The non-display area NA may include various wirings and driving circuits 311 for driving the plurality of pixels PX disposed in the display area AA. The driving circuit 311 may include a driving integrated circuit. For example, the driving circuit 311 may be a data driving circuit and/or a gate driving circuit, but is not limited thereto.

The non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1 and may be a bendable area. The second non-display area NA2 is an area extending from the bending area BA, and the pad part PAD may be disposed.

A plurality of link lines LL may be disposed in the non-display area NA. The plurality of link lines LL may extend from a plurality of pad electrodes PE of the second non-display area NA2 toward the bending area BA and the first non-display area NA1 and may be electrically connected to a plurality of driving lines VL of the display area AA. The plurality of driving lines VL may be disposed in the display area AA and electrically connected to each of the plurality of pixel driving circuits PD. Accordingly, the plurality of pixel driving circuits PD may be driven by receiving signals from one or more flexible circuit boards 310 and printed circuit boards 330 through the driving lines VL in the display area AA and the link line LL in the non-display area NA.

A pad part PAD including a plurality of pad electrodes PE may be disposed in the second non-display area NA2. The plurality of pad electrodes PE of the pad part PAD may be electrically connected to one or more flexible circuit boards 310. Also, the printed circuit board 330 may be electrically connected to one or more flexible circuit boards 310 and may supply a signal to the driving integrated circuit 311 mounted on the flexible circuit board 310. Accordingly, the pad part PAD may transmit various signals received from the printed circuit board 330 and the flexible circuit board 310 to the plurality of pixel driving circuits PD.

The driving circuit unit 300 may further include a timing controller 350, a power management integrated circuit 370, and a touch integrated circuit 390. The timing controller 350 may control a driving timing of each of the driving integrated circuit 311 and the plurality of pixel driving circuits PD based on a timing synchronization signal. The power management integrated circuit 370 may generate and output various power sources for driving the display device 1000. The touch integrated circuit 390 may supply a touch driving signal to the touch electrode in response to the touch synchronization signal supplied from the timing controller 350.

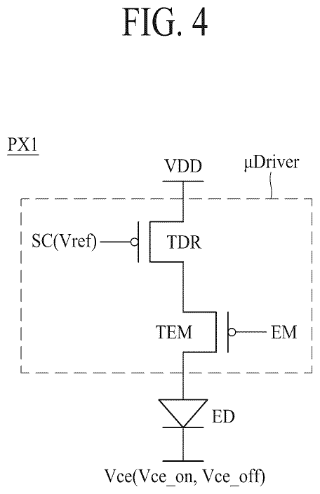

FIG. 4 is a diagram illustrating a circuit of a pixel PX according to an embodiment of the present disclosure. FIG. 4 is a diagram illustrating one micro-driver included in each of the plurality of pixel driving circuits PD illustrated in FIG. 3.

FIG. 4 illustrates that one light emitting device ED is connected to one micro-driver (μDriver), but is not limited thereto. For example, 8 light emitting devices ED, 16 light emitting devices ED, 32 light emitting devices ED or 64 light emitting devices ED may be connected to one micro-driver (μDriver). In addition, the light emitting device ED may be a micro light emitting device, a micro light emitting diode, or a micro light emitting diode chip. The light emitting device ED may have a scale of 1 μm to 100 μm, but is not limited thereto.

One micro-driver (μDriver) may include a driving transistor TDR and a light emitting transistor TEM, but embodiments of the present disclosure are not limited thereto. A high potential power voltage VDD may be applied to a first electrode of the driving transistor TDR, a first electrode of the light emitting transistor TEM may be connected to a second electrode of the driving transistor TDR, and a scan signal SC may be applied to a gate electrode of the driving transistor TDR. The second electrode of the driving transistor TDR may be connected to a first electrode of the light emitting transistor TEM, the light emitting device ED may be connected to a second electrode of the light emitting transistor TEM, and a light emitting signal EM may be applied to a gate electrode of the light emitting transistor TEM. Each of the driving transistor TDR and the light emitting transistor TEM may be an n-type transistor or a p-type transistor.

A first electrode of the light emitting device ED may be connected to the second electrode of the light emitting transistor T_{EM}, and a second electrode of the light emitting device ED may be connected to ground. For example, the first electrode of the light emitting device ED may be an anode, and the second electrode of the light emitting device ED may be a cathode, but embodiments of the present disclosure are not limited thereto. The voltage applied to the first electrode of the light emitting device ED from the light emitting transistor T_{EM} may be an anode voltage. The voltage applied to the low-potential power line may be a cathode voltage Vce. The cathode voltage Vce may be a cathode-on voltage Vce-on or a cathode-off voltage Vce_off. When the driving transistor T_{DR} and the light emitting transistor T_{EM} are turned on, a driving current may be applied to the light emitting device ED via the driving transistor TDR and the light emitting transistor TEM. Accordingly, the light emitting device ED may emit light.

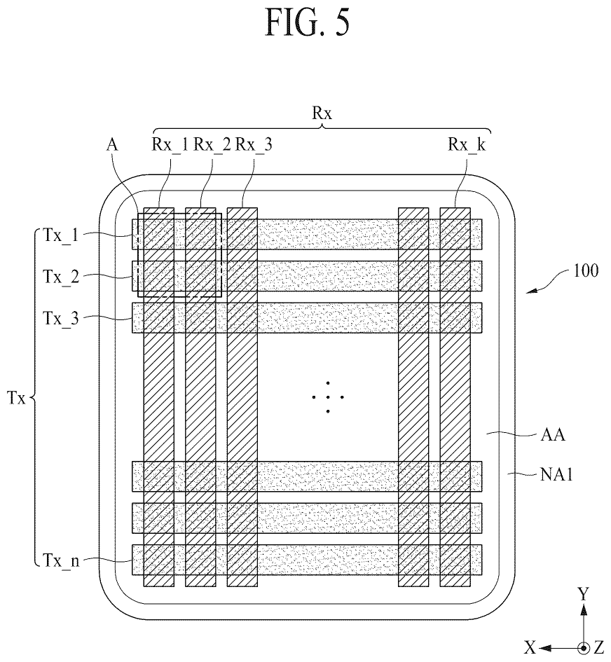

FIG. 5 is a plan view of a first display area of a display device according to an embodiment of the present disclosure. In particular, FIG. 5 illustrates a touch electrode structure in a mutual-capacitance type.

Referring to FIG. 5, the display device may include a plurality of Tx electrodes Tx and a plurality of Rx electrodes Rx. The plurality of Tx electrodes Tx may extend along the row direction (or the first direction X) and may be spaced apart along the column direction (or the second direction Y). Further, the plurality of Rx electrodes Rx may be disposed on the plurality of Tx electrodes Tx and may be disposed to cross the plurality of Tx electrodes Tx. The plurality of Rx electrodes Rx may extend along the column direction (or the second direction Y) and may be spaced apart along the row direction (or the first direction X).

The plurality of Tx electrodes Tx may receive a touch driving signal. In addition, the plurality of Rx electrodes Rx may receive a touch sensing signal and may form capacitance with the plurality of Tx electrodes Tx. Accordingly, the touch driving signal may be applied to one or more Tx electrodes Tx and the touch sensing signal may be received from one or more Rx electrodes Rx to detect a change in capacitance between the Tx electrode Tx and the Rx electrode Rx. Accordingly, a presence or absence of the touch and the position of the touch may be detected.

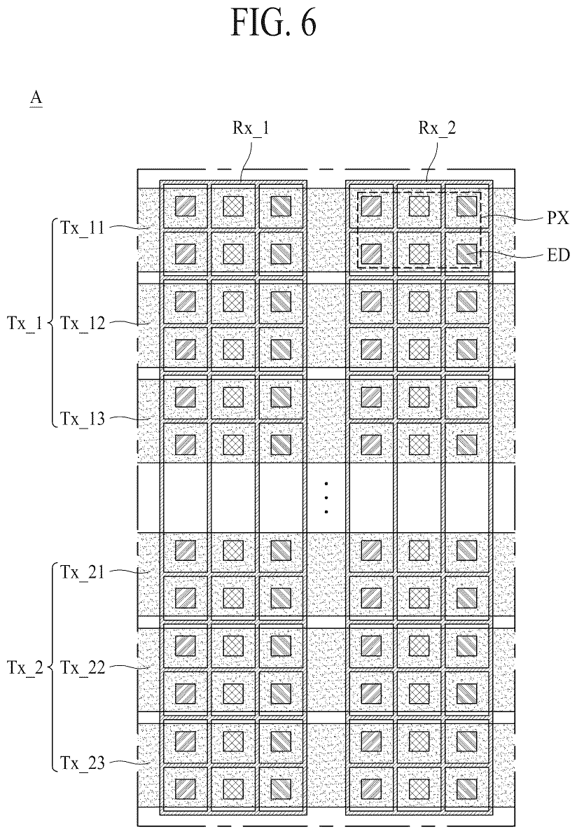

FIG. 6 is an enlarged view of an area A of FIG. 5 according to one embodiment. In detail, FIG. 6 illustrates a partial region including the plurality of Tx electrodes Tx and a partial region including the plurality of Rx electrodes Rx.

Referring to FIG. 6, the plurality of Tx electrodes Tx may include a first Tx electrode Tx_1 and a second Tx electrode Tx_2. The first Tx electrode Tx_1 may include a 1-1th Tx electrode Tx_11, a 1-2th Tx electrode Tx_12, and a 1-3th Tx electrode Tx_13. The 1-11th Tx electrode Tx_11, the 1-2th Tx electrode Tx_12, and the 1-3th Tx electrode Tx_13 may receive the same signal. In addition, the second Tx electrode Tx_2 may include a 2-1th Tx electrode Tx_21, a 2-2th Tx electrode Tx_22 and a 2-3th Tx electrode Tx_23. The 2-1th Tx electrode Tx_21, the 2-2th Tx electrode Tx_22, and the 2-3th Tx electrode Tx_23 may receive the same signal.

That is, each of the first Tx electrode Tx_1 and the second Tx electrode Tx_2 may include a plurality of electrodes receiving the same signal. Accordingly, an area of the Tx electrode Tx receiving the same signal is increased so that the signal may be stably applied. FIG. 6 illustrates that each of the first Tx electrode Tx_1 and the second Tx electrode Tx_2 includes three electrodes, but the present disclosure is not limited thereto.

The plurality of Rx electrodes Rx may include a first Rx electrode Rx_1 and a second Rx electrode Rx_2. Each of the first Rx electrode Rx_1 and the second Rx electrode Rx_2 may have a mesh shape.

A plurality of pixels PX may be disposed under the plurality of Tx electrodes Tx. Each of the plurality of pixels PX may be disposed in a region where the plurality of Tx electrodes Tx and the plurality of Rx electrodes Rx cross each other. FIG. 6 illustrates that one-pixel PX is disposed in a region where one Tx electrode Tx and one Rx electrode Rx cross each other, but the present disclosure is not limited thereto. Each of the plurality of pixels PX may include a plurality of light emitting devices ED. The first Rx electrode Rx_1 and the second Rx electrode Rx_2 may be disposed between the light emitting devices ED adjacent to each other. That is, the first Rx electrode Rx_1 and the second Rx electrode Rx_2 may not overlap the plurality of light emitting devices ED.

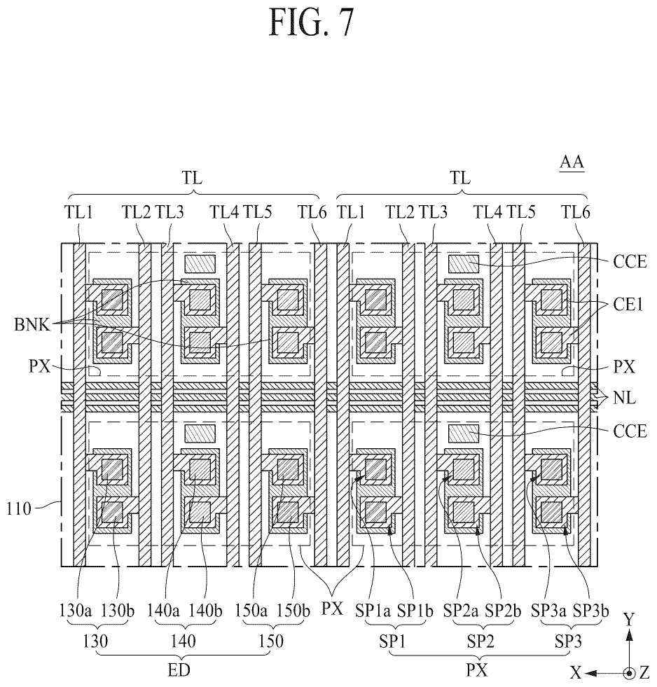

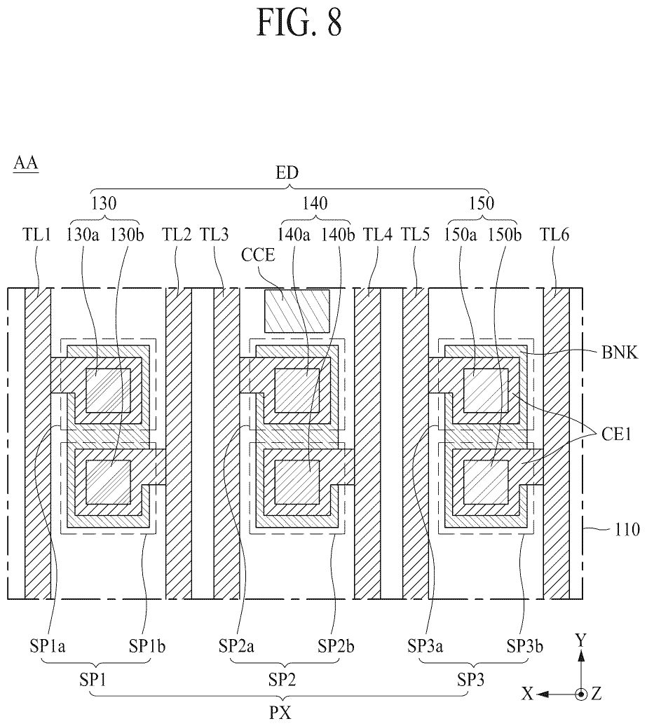

FIGS. 7 and 8 are a plan view of a display area of a display device according to an embodiment of the present disclosure. Specifically, FIG. 7 is an enlarged view of a display area AA including a plurality of pixels PX, and FIG. 8 is an enlarged view showing one-pixel PX.

FIGS. 7 and 8 illustrate a plurality of signal lines TL, a plurality of communication lines NL, a plurality of first electrodes CE1, a plurality of banks BNK, and a plurality of light emitting devices ED.

Referring to FIGS. 7 and 8, a plurality of pixels PX including a plurality of sub-pixels may be disposed in the display area AA. Each of the plurality of sub-pixels includes a light emitting device ED and may independently emit light. The plurality of sub-pixels may be configured in a plurality of rows and a plurality of columns and may be disposed in a matrix form, but embodiments of the present disclosure are not limited thereto.

The plurality of sub-pixels may include a first sub-pixel SP1, a second sub-pixel SP2, and a third sub-pixel SP3. The first sub-pixel SP1, the second sub-pixel SP2, and the third sub-pixel SP3 may be disposed in the row direction (or the first direction X). In addition, any one of the first sub-pixel SP1, the second sub-pixel SP2, and the third sub-pixel SP3 may be a red sub-pixel, another may be a green sub-pixel, and the other may be a blue sub-pixel.

Each of the plurality of pixels PX may include one or more first sub-pixels SP1, one or more second sub-pixels SP2, and one or more third sub-pixels SP3. For example, one-pixel PX may include a pair of first sub-pixels SP1, a pair of second sub-pixels SP2, and a pair of third sub-pixels SP3.

The pair of first sub-pixels SP1 may include a 1-1th sub-pixel SP1a and a 1-2th sub-pixel SP1b. The pair of second sub-pixels SP2 may include a 2-1th sub-pixel SP2a and a 2-2th sub-pixel SP2b. The pair of third sub-pixels SP3 may include a 3-1th sub-pixel SP3a and a 3-2th sub-pixel SP3b. That is, one-pixel PX may include the 1-1th sub-pixel SP1a, the 1-2th sub-pixel SP2a, the 2-1th sub-pixel SP2a, the 2-2th sub-pixel SP2b, the 3-1th sub-pixel SP3a, and the 3-2th sub-pixel SP3b.

In one-pixel PX, the plurality of sub-pixels may be variously arranged. For example, in one-pixel PX1, the pair of first sub-pixels SP1 may be disposed in the same column, the pair of second sub-pixels SP2 may be disposed in the same column, and the pair of third sub-pixels SP3 may be disposed in the same column. In addition, the first sub-pixel SP1, the second sub-pixel SP2, and the third sub-pixel SP3 may be disposed in the same row.

The plurality of signal lines TL may be disposed in an area between the plurality of sub-pixels. The plurality of signal lines TL may extend in the column direction (or a second direction Y) between the plurality of sub-pixels. The plurality of signal lines TL may be lines that transmit the anode voltage from the pixel driving circuit PD (showed in FIG. 3) to the plurality of sub-pixels.

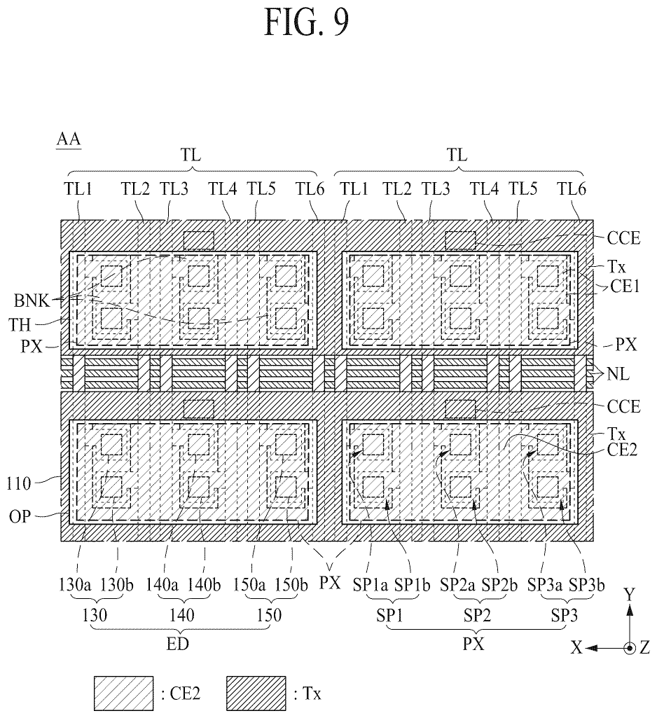

Specifically, the plurality of signal lines TL may be electrically connected to the plurality of pixel driving circuits PD (showed in FIG. 3) and the first electrode CE1 of the plurality of sub-19 pixels. The anode voltage output from the pixel driving circuit PD (showed in FIG. 3) may be transmitted to the first electrode CE1 of the plurality of sub-pixels through the plurality of signal lines TL. In addition, the first electrode CE1 may be an electrode electrically connected to the anode 134 of the light emitting device ED (showed in FIG. 9). Accordingly, the anode voltage from the signal line TL may be transmitted to the anode 134 of the light emitting device ED (showed in FIG. 9) through the first electrode CE1.

Therefore, instead of forming a plurality of transistors and storage capacitors in each of the plurality of sub-pixels, a structure of the display device 1000 may be simplified by using a pixel driving circuit PD (showed in FIG. 3) in which the plurality of pixel circuits are integrated in one pixel driving circuit PD (showed in FIG. 3). In addition, since a circuit disposed in each of the plurality of sub-pixels is integrated in one pixel driving circuit PD (showed in FIG. 3), high efficiency and low power driving may be possible.

The plurality of signal lines TL may include a first signal line TL1, a second signal line TL2, a third signal line TL3, a fourth signal line TL4, a fifth signal line TL5, and a sixth signal line TL6. Each of the first signal line TL1 and the second signal line TL2 may be electrically connected to each of the pair of first sub-pixels SP1. The third signal line TL3 and the fourth signal line TLA may be electrically connected to each of the pair of second sub-pixels SP2. Each of the fifth signal line TL5 and the sixth signal line TL6 may be electrically connected to each of the pair of third sub-pixels SP3. The plurality of signal lines TL may be formed of a conductive material. In addition, the plurality of signal lines TL may be formed of a multilayer structure of a conductive material.

The plurality of communication lines NL may be disposed in an area between the plurality of first pixels PX1. The plurality of communication lines NL may be wirings used for short-range communication such as near field communication (NFC) and may function as antennas.

Banks BNK may be disposed in each of the plurality of sub-pixels. The plurality of banks BNK may guide positions of the plurality of light emitting devices ED in a transfer process of the plurality of light emitting devices ED. That is, the plurality of light emitting devices ED may be transferred onto the plurality of banks BNK in the transfer process of the plurality of light emitting devices ED. An entire area of the light emitting device ED may overlap the bank BNK.

The bank BNK of the first sub-pixel SP1, the bank BNK of the second sub-pixel SP2, and the bank BNK of the third sub-pixel SP3 may be disposed to be spaced apart from each other. In addition, the bank BNK of the first sub-pixel SP1, the bank BNK of the second sub-pixel SP2, and the bank BNK of the third sub-pixel SP3 may be configured to be separated.

The plurality of banks BNK may be formed of an organic insulating material. In addition, the plurality of banks BNK may be formed of a single layer or a multilayer of an organic insulating material. For example, the plurality of banks BNK may be formed of a photo resist, a polyimide (PI), an acryl-based material, or the like, but embodiments of the present disclosure are not limited thereto.

The first electrode CE1 may be disposed in each of the plurality of sub-pixels. The first electrode CE1 may be disposed on the bank BNK. At least a portion of the first electrode CE1 may extend to an outside of the bank BNK to be electrically connected to the signal line TL closest to the first electrode CE1. A portion of the first electrode CE1 may overlap the bank BNK, and the remaining area of the first electrode CE1 may not overlap the bank BNK.

The first electrode CE1 is electrically connected to the anode 134 (showed in FIG. 9) of the light emitting device ED. The anode voltage from the pixel driving circuit PD (showed in FIG. 3) may be transmitted to the light emitting device ED via the signal line TL and the first electrode CE1. The pixel driving circuit PD (showed in FIG. 3) may apply the same voltage (or anode voltage) to the first electrode CE1 in each of the plurality of sub-pixels, but is not limited thereto.

The first electrode CE1 may be formed of a conductive material. The first electrode CE1 may be formed integrally with the plurality of signal lines TL. In addition, the first electrode CE1 may be formed of the same conductive material as the plurality of signal lines TL, but embodiments of the present disclosure are not limited thereto.

The plurality of light emitting devices ED may be disposed on the first electrode CE1 to overlap the bank BNK and the first electrode CE1. The entire area of the plurality of light emitting devices ED may overlap the bank BNK and the first electrode CE1. In addition, the plurality of light emitting devices ED are in contact with the first electrode CE1 and may be electrically connected to the first electrode CE1. Accordingly, the light emitting device ED may emit light by receiving the anode voltage from the pixel driving circuit PD through the signal line TL and the first electrode CE1.

The plurality of light emitting devices ED may include a first light emitting device 130, a second light emitting device 140, and a third light emitting device 150.

The first light emitting device 130 may be disposed in the first sub-pixel SP1. The second light emitting device 140 may be disposed in the second sub-pixel SP2. The third light emitting device 150 may be disposed in the third sub-pixel SP3. One of the first light emitting device 130, the second light emitting device 140, and the third light emitting device 150 may be a red light emitting device, another may be a green light emitting device, and the other may be a blue light emitting device, but embodiments of the present disclosure are not limited thereto.

The first light emitting device 130 may include a 1-1th light emitting device 130a disposed in the 1-1th sub-pixel SP1a and a 1-2th light emitting device 130b disposed in the 1-2th sub-pixel SP1b. The second light emitting device 140 may include a 2-1th light emitting device 140a disposed in the 2-1th sub-pixel SP2a and a 2-2th light emitting device 140b disposed in the 2-2th sub-pixel SP2b. The third light emitting device 150 may include a 3-1th light emitting device 150a disposed in the 3-1th sub-pixel SP3a and a 3-2th light emitting device 150b disposed in the 3-2th sub-pixel SP3b.

FIG. 9 is a plan view of a display area of a display device according to a first embodiment of the present disclosure. Specifically, FIG. 9 is an enlarged view of FIG. 7 in which a plurality of second electrodes CE2 and a plurality of Tx electrodes Tx are additionally disposed. For convenience, an area overlapping the second electrode CE2 and the Tx electrode Tx is indicated by a dotted line.

The second electrode CE2 may be disposed in each of the plurality of sub-pixels. The second electrode CE2 may be disposed on the light emitting device ED. In addition, each of the plurality of second electrodes CE2 may be spaced apart from each other.

One second electrode CE2 may be disposed in one-pixel PX. In addition, one second electrode CE2 may cover all of the plurality of light emitting devices ED disposed in one-pixel PX. FIG. 9 illustrates that one second electrode CE2 covers the first light emitting device 130, the second light emitting device 140, and the third light emitting device 150.

Although not shown in FIG. 9, the second electrode CE2 may be electrically connected to the pixel driving circuit PD (showed in FIG. 3). The second electrode CE2 may be electrically connected to the cathode 135 (showed in FIG. 9) of the light emitting device ED to transmit the cathode voltage from the pixel driving circuit PD (showed in FIG. 3) to the light emitting device ED.

The cathode voltage applied to each of the plurality the second electrode CE2 may be the same. For example, the cathode voltage may be commonly applied to the plurality of second electrodes CE2 and the cathode electrodes 135 of the light emitting device ED (showed in FIG. 9). In addition, the cathode voltage applied to the plurality of second electrode CE2 may be changed according to a reference voltage Vref (showed in FIG. 4). For example, the cathode voltage may be adjusted based on screen brightness by user's manipulation.

The plurality of Tx electrodes Tx are disposed on the plurality of pixels PX and may be disposed on the light emitting device ED. The plurality of Tx electrodes Tx does not overlap the plurality of pixels PX and may surround the plurality of pixels PX. The plurality of Tx electrodes Tx may be disposed in an outer area of each of the plurality of pixels PX. In addition, each of the plurality of Tx electrodes Tx may be spaced apart from each other.

Each of the plurality of Tx electrodes Tx may include a plurality of opening areas OP. Each of the plurality of second electrodes CE2 may be disposed in the plurality of opening areas OP. One Tx electrode Tx may surround each of the plurality of second electrodes CE2 and may be spaced apart from the plurality of second electrodes CE2. That is, an area of one second electrode CE2 may be smaller than an area of one opening area OP. In addition, the plurality of Tx electrodes Tx may be disposed on the same layer as the plurality of second electrodes CE2.

Due to the difference between the area of one second electrode CE2 and the area of one opening area OP, a through hole TH may be disposed between the adjacent Tx electrode Tx and the second electrode CE2. The through hole TH may surround the second electrode CE2, and the Tx electrode Tx may surround the through hole TH. In addition, the through hole TH may not overlap the light emitting device ED. In addition, the through hole TH may overlap or may not overlap the signal line TL.

A plurality of contact electrodes CCE may be disposed on the substrate 110. The plurality of contact electrodes CCE may be spaced apart from the plurality of banks BNK and the plurality of signal lines TL. Each of the plurality of Tx electrodes Tx may overlap at least one contact electrode CCE. For example, one Tx electrode Tx may overlap the plurality of contact electrodes CCE.

The plurality of Tx electrodes Tx may be electrically connected to the pixel driving circuit PD (showed in FIG. 3) through the plurality of contact electrodes CCE. The plurality of Tx electrodes Tx may receive a touch driving signal from the pixel driving circuit PD (showed in FIG. 3).

The plurality of Tx electrodes Tx may have a size corresponding to one row (or horizontal line). For example, each of the plurality of Tx electrodes Tx may have a width corresponding to one row (or horizontal line) and may extend along the column direction (or the first direction X). In addition, each of the plurality of Tx electrodes Tx may surround the light emitting device ED in each of the plurality of pixels PX disposed along the column direction (or the first direction X).

In addition, the plurality of Tx electrodes Tx may surround the light emitting element ED in each of 16, 96, or 192 pixels PX disposed along the column direction (or the first direction X).

Some of the plurality of Tx electrodes Tx may be separated from each other. For example, the plurality of Tx electrodes Tx connected to the pixels PX of the nth row and the plurality of Tx electrodes Tx connected to the pixels PX of the n+1th row may be separated from each other. In addition, the plurality of Tx electrodes Tx may be spaced apart from each other with the plurality of communication lines NL extending in a row direction interposed therebetween.

A plurality of communication lines NL may be disposed in an area between the plurality of Tx electrodes Tx and may not overlap the plurality of Tx electrodes Tx. in addition, the plurality of communication lines NL may be disposed in an area between the plurality of second electrodes CE2 and may not overlap the plurality of second electrodes CE2.

The plurality of second electrodes CE2 and the plurality of Tx electrodes Tx may be formed of a transparent conductive material, but embodiments of the present disclosure are not limited thereto. The plurality of second electrodes CE2 and the plurality of Tx electrodes Tx may be formed of the transparent conductive material so that light emitted from the light emitting device ED is directed to an upper portion of the second electrode CE2 and the plurality of Tx electrodes Tx. For example, the second electrode CE2 and the plurality of Tx electrodes Tx may be formed of the transparent conductive material such as indium tin oxide (ITO), indium zinc oxide (IZO), indium gallium zinc oxide (IGZO), or the like, but embodiments of the present disclosure are not limited thereto.

The plurality of second electrodes CE2 and the plurality of Tx electrodes Tx are formed of the same material and may be formed through the same process. For example, after depositing one metal layer, a partial area of the metal layer may be etched to form the through hole TH. In this case, the metal layer disposed inside the through hole TH may become the second electrode CE2, and the metal layer disposed outside the through hole TH may become the Tx electrode Tx. Accordingly, the manufacture process may be simplified by simultaneously forming the plurality of second electrodes CE2 and the plurality of Tx electrodes Tx. That is, by optimizing the manufacture process, production energy may be reduced.

When the light emitting device ED is formed of a micro light emitting diode chip, the micro light emitting diode chip may be transferred to the substrate 110 to manufacture the display panel 100. Various defects may occur in the process of transferring the plurality of light emitting devices ED having a micro size from the wafer to the substrate 110. In consideration of defects occurring during the transfer process of the plurality of light emitting devices ED, a plurality of the same type of light emitting devices ED may be transferred to one sub-pixel. In this case, a lighting test of the plurality of light emitting devices ED is performed, and only one light emitting device ED that has finally been determined to be normal may be used. That is, even if the plurality of the same type of light emitting devices ED are transferred to one first pixel PX1, only one light emitting device ED may be finally used. In this case, any one of the pair of light emitting devices ED may be a main or primary light emitting device ED, and the other light emitting device ED may be a redundancy light emitting device ED. The redundancy light emitting device ED may be an extra light emitting device ED transferred to prepare for a defect in the main light emitting device ED.

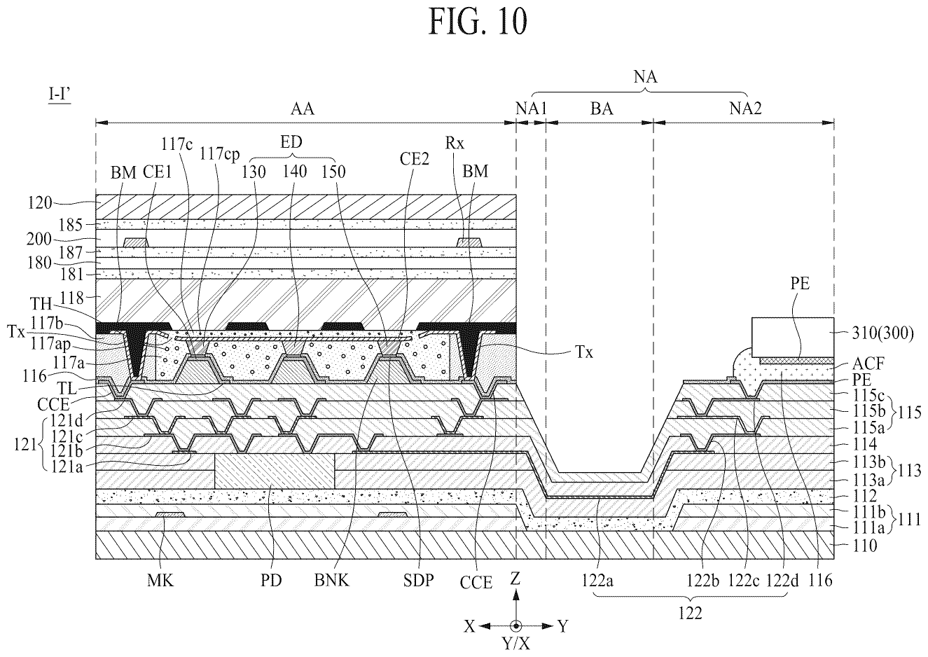

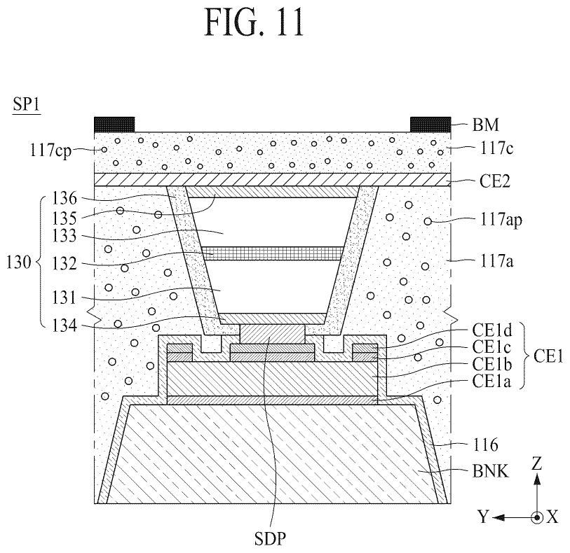

FIG. 10 is a cross-sectional view of a display device according to a first embodiment of the present disclosure. FIG. 10 is a cross-sectional view of the display area AA, the first non-display area NA, the bending area BA, and the second non-display area NA2 taken along line I-I′ shown in FIG. 2. Also, FIG. 11 is a cross-sectional view of a first light emitting element 130 according to an embodiment of the present disclosure.

Referring to FIG. 10, a buffer layer 111 is disposed on the substrate 110. The buffer layer 111 includes a first buffer layer 111a and a second buffer layer 111b. The first buffer layer 111a and the second buffer layer 111b may be disposed in the display area AA, the first non-display area NA1, and the second non-display area NA2. An upper surface of the substrate 110 disposed in the bending area BA may be exposed by the first buffer layer 111a and the second buffer layer 111b. Accordingly, cracks generated in the first buffer layer 111a and the second buffer layer 111b may be prevented or minimized when the bending area BA is bent. The first buffer layer 111a and the second buffer layer 111b may be formed of an inorganic insulating material. The first buffer layer 111a and the second buffer layer 111b may reduce penetration of moisture or impurities through the substrate 110.

A plurality of alignment keys MK may be disposed between the first buffer layer 111a and the second buffer layer 111b. The plurality of alignment keys MK may identify a position of the pixel driving circuit PD during a manufacturing process of the display panel 100. The plurality of alignment keys MK may be omitted.

An adhesive layer 112 may be disposed on the second buffer layer 111b. The adhesive layer 112 may be disposed in the display area AA, the first non-display area NA1, the bending area BA, and the second non-display area NA2. In addition, a portion of the adhesive layer 112 may be removed from the non-display area NA including the bending area BA.

In the display area AA, the pixel driving circuit PD may be disposed on the adhesive layer 112. The driving circuit PD may be supported by the buffer layer 111.

A protective layer 113 may be disposed on the adhesive layer 112 and the pixel driving circuit PD. The protective layer 113 may include a first protective layer 113a and a second protective layer 113b. The first protective layer 113a and the second protective layer 113b may be formed of an organic insulating material, but embodiments of the present disclosure are not limited thereto. The first protective layer 113a and the second protective layer 113b may surround a side surface of the pixel driving circuit PD, but embodiments of the present disclosure are not limited thereto. In addition, the second protective layer 113b may cover at least a portion of an upper surface of the pixel driving circuit PD.

A wiring layer may be disposed on the protective layer 113b. The wiring layer may surround or cover the pixel driving circuit PD. The wiring layer may include a plurality of first connection lines 121.

The plurality of first connection lines 121 may be disposed on the second protective layer 113b. The plurality of first connection lines 121 may electrically connect the pixel driving circuit PD to wirings in other components or different layers. For example, the pixel driving circuit PD may be electrically connected to the plurality of signal lines TL, the plurality of contact electrodes CCE, and the like through the plurality of first connection lines 121.

The plurality of first connection lines 121 may include a plurality of 1-1th connection lines 121a, a plurality of 1-2th connection lines 121b, a plurality of 1-3th connection lines 121c, and a plurality of 1-4th connection lines 121d. For example, the plurality of 1-1th connection lines 121a may be disposed on the second protective layer 113b and may transmit voltages output from the pixel driving circuit PD to the first electrode CE1 or the second electrode CE2.

A third protective layer 114 may be disposed on the second protective layer 113b. The third protective layer 114 may be disposed on the entire first display area AA1 and the non-display area NA.

The plurality of 1-2th connection lines 121b may be disposed on the third protective layer 114. The plurality of 1-2th connection lines 121b may be connected to the pixel driving circuit PD through the 1-1th connection lines 121a or may be directly connected to the pixel driving circuit PD.

The display device 1000 may further include an insulating layer 115 on the wiring layer. The insulating layer 115 may electrically insulate the plurality of first connection lines 121 from each other and may cover the plurality of first connection lines 121. The insulating layer 115 may include a first insulating layer 115a, a second insulating layer 115b and a third insulating layer 115c.

A first insulating layer 115a may be disposed on the plurality of 1-2th connection lines 121b. The first insulating layer 115a may be disposed in the entire display area AA and the non-display area NA, but embodiments of the present disclosure are not limited thereto. The first insulating layer 115a may be formed of an organic insulating material, but embodiments of the present disclosure are not limited thereto.

The plurality of 1-3th connection lines 121c may be disposed on the first insulating layer 115a. The plurality of 1-3th connection lines 121c may be electrically connected to the plurality of 1-2th connection lines 121b.

A second insulating layer 115b may be disposed on the plurality of 1-3th connection lines 121c. The second insulating layer 115b may be disposed in the remaining area except for the bending area BA, but embodiments of the present disclosure are not limited thereto.

The plurality of 1-4th connection lines 121d may be disposed on the second insulating layer 115b. The plurality of 1-4th connection lines 121d may be electrically connected to the plurality of 1-3th connection lines 121c.

The 1-4th connection line 121d may be connected to the contact electrode CCE through a contact hole of the third insulating layer 115c. Accordingly, the contact electrode CCE may be electrically connected to the pixel driving circuit PD by the first connection wiring 121. In addition, the 1-4th connection wiring 121d may be electrically connected to the signal line TL. Accordingly, the signal line TL may be electrically connected to the pixel driving circuit PD by the first connection line 121.

A plurality of second connection lines 122 may be disposed on the second protective layer 113b in the non-display area NA. The plurality of second connection lines 122 may transmit a signal received from the flexible circuit board 310 (showed in FIG. 2) and a printed circuit board 330 (showed in FIG. 2) to the pixel driving circuit PD of the display area AA.

The plurality of second connection lines 122 may extend from the pad part PAD (showed in FIG. 2) toward the display area AA to transmit signals to the wirings of the display area AA. In this case, the plurality of second connection lines 122 may function as link lines LL (showed in FIG. 3). The plurality of second connection lines 122 may include a 2-1th connection line 122a, a 2-2th connection line 122b, a 2-3th connection line 122c, and a 2-4th connection line 122d. A signal received from the flexible circuit board 310 (showed in FIG. 2) and the printed circuit board 330 (showed in FIG. 2) may be transmitted to the 2-1th connection line 122a through the 2-4th connection line 122d, the 2-3th connection line 122c, and the 2-2th connection line 122b.

The plurality of first connection lines 121 and the plurality of second connection lines 122 may be formed of a conductive material having excellent ductility or various conductive materials used in the display area AA.

A third insulating layer 115c may be disposed on the plurality of first connection lines 121 and the plurality of second connection lines 122. The third insulating layer 115c may be disposed in the display area AA, the first non-display area NA1, and the second non-display area NA2. At least a portion of the third insulating layer 115c in the bending area BA may be removed. The third insulating layer 115c may be formed of an organic insulating material, but embodiments of the present disclosure are not limited thereto.

A plurality of banks BNK may be disposed on the third insulating layer 115c in the first display area AA1. The plurality of banks BNK may overlap each of the plurality of sub-pixels. One or more light emitting devices ED of the same type may be disposed on an upper portion of each of the plurality of banks BNK.

In the display area AA, a plurality of signal lines TL may be disposed on the third insulating layer 115c. The plurality of signal lines TL may be disposed between the plurality of banks BNK. Each of the plurality of signal lines TL may be electrically connected to the first connection line 121, for example, the 1-4th connection line 121d.

A plurality of contact electrodes CCE may be disposed on the third insulating layer 115c in the display area AA. The plurality of contact electrodes CCE may supply the cathode voltage from the pixel driving circuit PD to the second electrode CE2. Each of the plurality of contact electrodes CCE may be electrically connected to the first connection line 121, for example, the 1-4th connection line 121d.

A first electrode CE1 may be disposed on the bank BNK. The first electrode CE1 may extend from the adjacent signal line TL to an upper portion of the bank BNK. The first electrode CE1 may be disposed on an upper surface of the bank BNK and a side surface of the bank BNK. The first electrode CE1 may be a contact electrode. In addition, the first electrode CE1 may be integrally formed with the signal line TL.

Referring to FIG. 11, the first electrode CE1 may include a plurality of conductive layers. For example, the first electrode CE1 may include a first conductive layer CE1a, a second conductive layer CE1b, a third conductive layer CE1c, and a fourth conductive layer CE1d, but embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. The first conductive layer CE1a, the second conductive layer CE1b, the third conductive layer CE1c, and the fourth conductive layer CE1d may be formed of titanium (Ti), molybdenum (Mo), aluminum (Al), or titanium (Ti) and indium tin oxide (ITO), but embodiments of the present disclosure are not limited thereto.

Among the plurality of conductive layers constituting the first electrode CE1, some conductive layers having good reflection efficiency may be used an alignment key for aligning the light emitting device ED and/or a reflector. For example, among the plurality of conductive layers constituting the first electrode CE1, the second conductive layer CE1b may include a reflective material. In order to form the second conductive layer CE1b as the reflector, the third conductive layer CE1c and the fourth conductive layer CE1d covering the second conductive layer CE1b may be partially removed or etched.

The first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO) that has good adhesion to the solder pattern SDP and has corrosion resistance and acid resistance.

As shown in FIGS. 10 and 11, the signal line TL, the contact electrode CCE, and the pad electrode PE disposed on the same layer as the first electrode CE1 may be configured as a multilayer structure of conductive material, but embodiments of the present disclosure are not limited thereto. For example, the signal line TL, the contact electrode CCE, and the pad electrode PE may be configured as a multilayer structure of indium tin oxide (ITO)/titanium (Al)/titanium (Ti), but embodiments of the present disclosure are not limited thereto.

A solder pattern SDP may be disposed on the first electrode CE1 in each of the plurality of sub-pixels. The solder pattern SDP may bond the light emitting device ED to the first electrode CE1. The first electrode CE1 and the light emitting device ED may be electrically connected to each other through eutectic bonding using the solder pattern SDP, but embodiments of the present disclosure are not limited thereto. For example, when the solder pattern SDP is formed of indium (In) and the anode 134 of the light emitting device ED is formed of gold (Au), the solder pattern SDP and the anode 134 may be bonded to each other by applying heat and pressure in the transfer process of the light emitting device ED. That is, the light emitting device ED may be bonded to the solder pattern SDP and the first electrode CE1 without an additional adhesive.

A passivation layer 116 may be disposed on the wiring layer. The passivation layer 116 may be disposed on the plurality of signal lines TL, the plurality of first electrodes CE1, the plurality of contact electrodes CCE, and the third insulation layer 115c. Since the passivation layer 116 covers the remaining areas while exposing at least a portion of the plurality of pad electrodes PE, the plurality of contact electrodes CCE, and the solder pattern SDP, penetration of moisture or impurities flowing into the light emitting device ED may be reduced. The passivation layer 116 may be formed of a single layer or multiple layers including silicon oxide (SiOx) or silicon nitride (SiNx), but embodiments of the present disclosure are not limited thereto.

In each of the plurality of sub-pixels, the light emitting device ED may be disposed on the solder pattern SDP. The first light emitting device 130 may be disposed in the first sub-pixel SP1. The second light emitting device 140 may be disposed in the second sub-pixel SP2. The third light emitting device 150 may be disposed in the third sub-pixel SP3.

Referring to FIG. 11, the first light emitting device 130 may include an anode 134, a first semiconductor layer 131, an active layer 132, a second semiconductor layer 133, a cathode 135, and an encapsulation layer 136, but embodiments of the present disclosure are not limited thereto. For example, the encapsulation layer 136 may not be included in the first light emitting device 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may include a compound semiconductor such as a group III-V or a group II-VI, and may be doped with impurities (or dopants). For example, one of the first semiconductor layer 131 and the second semiconductor layer 133 may be a semiconductor layer doped with n-type impurities, and the other may be a semiconductor layer doped with p-type impurities, but embodiments of the present disclosure are not limited thereto. Each of the first semiconductor layer 131 and the second semiconductor layer 133 may be a nitride semiconductor including an n-type impurity and a nitride semiconductor including a p-type impurity, but is not limited thereto.

At least one of the first semiconductor layer 131 and the second semiconductor layer 133 may be a layer in which an n-type or p-type impurity is doped into a material such as gallium nitride (GaN), gallium phosphide (GaP), gallium arsenic phosphide (GaAsP), aluminum gallium indium phosphide (AlGaInP), indium aluminum phosphide (InAIP), aluminum gallium nitride (AlGaN), aluminum indium nitride (AlInN), aluminum gallium nitride (AlInGaN), aluminum gallium arsenic (AlGaAs), gallium arsenic (AlGaAs), or a material such as gallium arsenic (GaAs), but embodiments of the present disclosure are not limited thereto. For example, the n-type impurity may be silicon (Si), germanium (Ge), selenium (Se), carbon (C), tellurium (Te), tin (Sn), or the like, but embodiments of the present disclosure are not limited thereto. For example, the p-type impurity may be magnesium (Mg), zinc (Zn), calcium (Ca), strontium (Sr), barium (Ba), beryllium (Be), or the like, but embodiments of the present disclosure are not limited thereto.

The active layer 132 may be disposed between the first semiconductor layer 131 and the second semiconductor layer 133. The active layer 132 may emit light by receiving holes and electrons from the first semiconductor layer 131 and the second semiconductor layer 133. For example, the active layer 132 may be formed of one of a single well structure, a multi-well structure, a single quantum well structure, a multi-quantum well (MQW) structure, a quantum dot structure, and a quantum line structure, but embodiments of the present disclosure are not limited thereto.

The anode 134 may be disposed between the first semiconductor layer 131 and the solder pattern SDP. The anode 134 may electrically connect the first semiconductor layer 131 to the first electrode CE1. The anode voltage output from the pixel driving circuit PD may be applied to the first semiconductor layer 131 through the signal line TL, the first electrode CE1, and the anode 134. For example, the anode 134 may be formed of a conductive material capable of eutectic bonding with the solder pattern SDP, but embodiments of the present disclosure are not limited thereto. For example, the anode 134 may be formed of gold (Au), tin (Sn), tungsten (W), silicon (Si), silicon (Ag), titanium (Ti), iridium (Ir), chromium (In), indium (Zn), zinc (Pb), lead (Ni), platinum (Pt), copper (Cu), or alloys thereof, but embodiments of the present disclosure are not limited thereto.

The cathode 135 may be disposed on the second semiconductor layer 133. For example, the cathode 135 may electrically connect the second semiconductor layer 133 to the second electrode CE2. The cathode voltage output from the pixel driving circuit PD may be applied to the second semiconductor layer 133 through the second electrode CE2, and the cathode 135. The cathode 135 may be formed of a transparent conductive material to allow light emitted from the light emitting device ED to be directed to an upper portion of the light emitting device ED, but embodiments of the present are not limited thereto.

The encapsulation layer 136 may be disposed on at least a portion of each of the first semiconductor layer 131, the active layer 132, the second semiconductor layer 133, the anode 134, and the cathode 135. The encapsulation layer 136 may protect the first semiconductor layer 131, the active layer 132, and the second semiconductor layer 133.

According to the present disclosure, the light emitting device ED has been described as a vertical structure, but embodiments of the present disclosure are not limited thereto. For example, the light emitting device ED may have a lateral structure or a flip chip structure.

Although the first light emitting device 130 has been described with reference to FIG. 11, the second light emitting device 140 and the third light emitting device 150 may have substantially the same structure as the first light emitting device 130. For example, the second light emitting device 140 and the third light emitting device 150 may have substantially the same configuration as the first semiconductor layer 131, the active layer 132, the second semiconductor layer 133, the anode 134, the cathode 135, and the encapsulation layer 136.

As shown in FIGS. 10 and 11, the display device 1000 may further include optical layers 117a, 117b and 117c.

The optical layers 117a, 117b and 117c may surround the plurality of light emitting devices ED in the first display area AA1. For example, the optical layers 117a, 117b and 117c may be configured to cover the plurality of light emitting devices ED in the display area AA.

A first optical layer 117a may cover side surfaces of the plurality of light emitting devices ED and side surfaces of the plurality of banks BNK in the plurality of sub-pixels. In addition, the first optical layer 117a may cover the first electrode CE1, a portion of the passivation layer 116, and an area between the plurality of light emitting devices ED. In addition, the first optical layer 117a may be disposed between the plurality of light emitting devices ED and between the plurality of banks BNK included in one-pixel PX.

The first optical layer 117a may include an organic insulating material in which fine particles 117ap are distributed. For example, the first optical layer 117a may be formed of siloxane in which fine particles 117ap such as titanium dioxide (TiO₂) particles are distributed, but embodiments of the present disclosure are not limited thereto. Light from the plurality of light emitting devices ED may be scattered by fine particles 117ap distributed in the first optical layer 117a and emitted to an outside of the display panel 100. Accordingly, the first optical layer 117a may improve extraction efficiency of light emitted from the plurality of light emitting devices ED.

The second optical layer 117b may be disposed on the passivation layer 116 in the first display area AA1. The second optical layer 117b may surround the first optical layer 117a. In addition, the second optical layer 117b may be in contact with a side surface of the first optical layer 117a. In addition, the second optical layer 117b may be disposed in an area between the plurality of pixels PX, but embodiments of the present disclosure are not limited thereto.

The second optical layer 117b may be formed of an organic insulating material. The second optical layer 117b may be formed of the same material as the first optical layer 117a, but embodiments of the present disclosure are not limited thereto. For example, the first optical layer 117a may include fine particles, and the second optical layer 117b may not include fine particles.

A thickness of the first optical layer 117a may be less than a thickness of the second optical layer 117b. An upper surface of the second optical layer 117b may be a flat surface, and an upper surface of the first optical layer 117a may be a concave curved surface. Accordingly, when viewed in a plan view, an area in which the first optical layer 117a is disposed may include a concave portion recessed from the upper surface of the second optical layer 117b.

The second electrode CE2 may be disposed on the first optical layer 117a. The second electrode CE may overlap the first optical layer 117a and may not overlap the second optical layer 117b. That is, an end of the second electrode CE2 may be disposed on the upper surface of the first optical layer 117a.

The second electrode CE2 may be disposed on the plurality of light emitting devices ED. In addition, the second electrode CE2 may be in contact with the cathode electrode 135. The one second electrode CE2 may be commonly connected to the plurality of light emitting devices ED in one-pixel PX arranged along the row direction (or the first direction X) of the substrate 110. In FIG. 10, since one-pixel PX includes the first to third light emitting devices 130, 140, and 150, one second electrode CE2 may be commonly connected to the first to third light emitting devices 130, 140, and 150.

As described above, a region in which the first optical layer 117a is disposed may include a concave portion recessed from the upper surface of the second optical layer 117b. Since the second electrode CE2 is disposed on the upper surface of the first optical layer 117a, the second electrode CE2 may have a concave shape along the concave portion of the first optical layer 117a. That is, the second electrode CE2 may be disposed at a position lower than the second optical layer 117b.

The Tx electrode Tx is disposed on the second optical layer 117b and may overlap the second optical layer 117b. A partial area of the Tx electrode Tx is disposed on the first optical layer 117a and may overlap the first optical layer 117a. FIG. 10 shows that an end of the Tx electrode Tx is disposed on an upper surface of the first optical layer 117a. In this case, a partial area of the Tx electrode Tx disposed on the first optical layer 117a is disposed along the concave portion, and thus may be disposed at a position lower than the remaining portion of the Tx electrode Tx disposed on the second optical layer 117b.

Since both the first optical layer 117a and the second optical layer 117b are material layers disposed on the passivation layer 116, the Tx electrode Tx may be disposed on the same layer as the second electrode CE2.

A through hole TH may be disposed between the second electrode CE2 and the Tx electrode Tx. The second electrode CE2 and the Tx electrode Tx may be spaced apart from each other by the through hole TH. The through hole TH may overlap the first optical layer 117a.

The Tx electrode Tx may be electrically connected to the plurality of contact electrodes CCE through contact holes of the second optical layer 117b. Through the plurality of contact electrodes CCE, the Tx electrode Tx may receive the touch driving signal from the pixel driving circuit PD.

A third optical layer 117c may be disposed on the second electrode CE2 and the Tx electrode Tx. The third optical layer 117c may overlap the plurality of light emitting devices ED and the first optical layer 117a, and not to overlap the second optical layer 117b. In addition, the third optical layer 117c may fill an inside of the through hole TH.

The third optical layer 117c may be formed of an organic insulating material in which fine particles 117cp are distributed. For example, the third optical layer 117c may be formed of siloxane in which fine particles 117cp such as titanium dioxide (TiO2) particles are distributed, but embodiments of the present disclosure are not limited thereto. In addition, the third optical layer 117c may be formed of the same material as the first optical layer 117a, but embodiments of the present disclosure are not limited thereto.

Light from the plurality of light emitting devices ED may be scattered by fine particles 117cp distributed in the third optical layer 117c and emitted to the outside of the display panel 100. The third optical layer 117c may evenly mix the light emitted from the plurality of light emitting devices ED to further improve luminance uniformity of the display device. In addition, light extraction efficiency of the display device may be improved by the light scattered from the plurality of fine particles 117cp, and thus the display device may be driven at a low power.

In the display area AA, a black matrix BM may be disposed on the second electrode CE2, the Tx electrode Tx, the first optical layer 117a, the second optical layer 117b, and the third optical layer 117c. The black matrix BM may overlap the Tx electrode Tx. The black matrix BM may fill a contact hole of the second optical layer 117b. In addition, since the black matrix BM is disposed within a contact hole in which the Tx electrode Tx and the contact electrode CCE are connected, light leakage between the plurality of adjacent sub-pixels may be prevented or at least reduced. The black matrix BM may be an organic insulating material to which a black pigment or a black dye is added, but embodiments of the present disclosure are not limited thereto.

The display device 1000 may further include a cover layer 118. The cover layer 118 may cover the display area AA and may protect the plurality of light emitting devices ED. The cover layer 118 may be formed of organic insulating material, but embodiments of the present disclosure are not limited thereto.

A polarizing layer 180 may be disposed on the cover layer 118 via a first adhesive layer 181. A cover member 120 may be disposed on the polarizing layer 180 via a second adhesive layer 185. The polarizing layer 180 may be attached to a rear surface of a touch panel 200 via a third adhesive layer 187.

An insulating layer 200 may be attached to a rear surface of the cover member 120 via the second adhesive layer 185. The insulating layer 200 may include a Rx electrode Rx. The Rx electrode Rx may overlap the black matrix BM, and may not overlap the light emitting device ED. Accordingly, it is possible to minimize a reduction of the light efficiency of the light emitting device ED.

The Rx electrode Rx may overlap the Tx electrode Tx. Accordingly, a touch may be detected through a change in capacitance between the Tx electrode Tx and the Rx electrode Rx.

Generally, a touch panel in a mutual-capacitance type discloses a Tx electrode, an Rx electrode, and a touch insulating layer disposed between the Tx electrode and the Rx electrode. However, the present disclosure discloses that a metal layer disposed in the same layer as the second electrode CE2 and disposed in an outer area of the pixel PX is used as the Tx electrode Tx. Accordingly, only the Rx electrode Rx is additionally formed on the second electrode CE2, and a touch may be detected by using an insulating layer such as a cover layer 118 disposed between the second electrode CE2 and the Rx electrode Rx as a touch insulating layer. Accordingly, a thickness of the display device may be reduced and the manufacture process may be simplified. That is, by optimizing the manufacture process, production energy may be reduced.

The plurality of pad electrodes PE may be disposed on the third insulating layer 115c in the second non-display area NA2. In addition, an adhesive film ACF may be disposed between the plurality of pad electrodes PE and the flexible circuit board 170 to attach or bond the flexible circuit board 310 to the plurality of pad electrodes PE.

The flexible circuit board 310 may be disposed on the adhesive film ACF. The flexible circuit board 310 may be electrically connected to the plurality of pad electrodes PE through the adhesive film ACF. The signals output from the printed circuit board 330 may be transmitted to the pixel driving circuit PD of the display area AA through the flexible circuit board 310, the plurality of pad electrodes PE, the 2-4th connection line 122d, the 2-3th connection line 122c, the 2-1th connection line 122b, and the 2-1th connection line 122a.

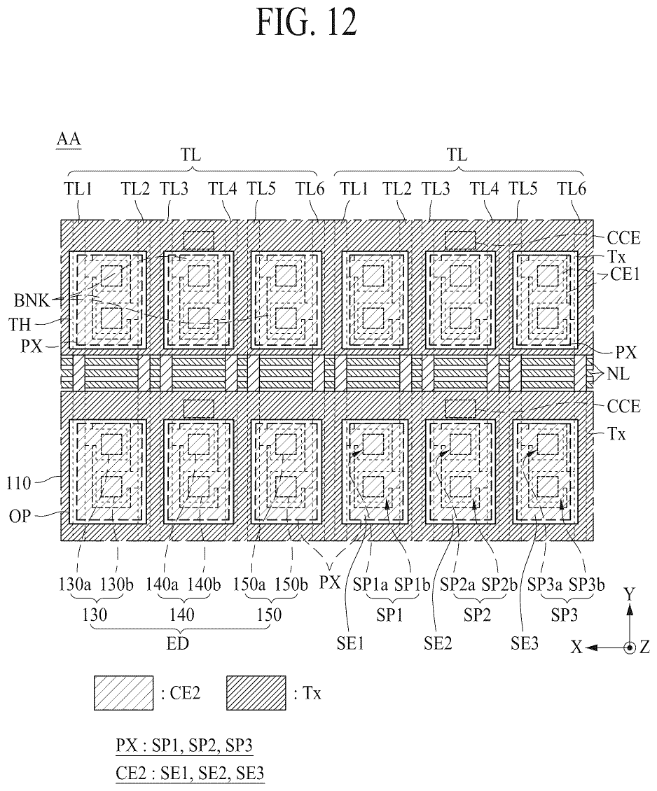

FIG. 12 is a plan view of a display area of a display device according to a second embodiment of the present disclosure.

Compared to the structure of the display area AA shown in FIG. 9, the display area AA shown in FIG. 12 includes the same configuration as the display area AA of FIG. 9 except for the structure of the plurality of second electrodes CE2 and the plurality of Tx electrodes Tx, and thus the description of the same configuration will be omitted.

As described above, the plurality of second electrodes CE2 may be disposed in each of a plurality of pixels PX and may be disposed on the light emitting device ED. In addition, each of a plurality of second electrodes CE2 may be spaced apart from each other. One second electrode CE2 may be disposed in one-pixel PX.

In this case, one second electrode CE2 may include a plurality of sub-electrodes SE. Referring to FIG. 12, one second electrode CE2 may include a first sub-electrode SE1, a second sub-electrode SE2, and a third sub-electrode SE3.

The first sub-electrode SE1 may be disposed in the first sub-pixel SP1, the second sub-electrode SE2 may be disposed in the second sub-pixel SP2, and the third sub-electrode SE3 may be disposed in the third sub-pixel SP3. The first sub-electrode SE1, the second sub-electrode SE2 and the third sub-electrode SE3 may be spaced apart from each other.

The first sub-electrode SE1 may cover the first light emitting device 130, the second sub-electrode SE2 may cover the second light emitting device 140, and the third sub-electrode SE3 may cover the third light emitting device 150.

Although not shown in FIG. 12, each of the first sub-electrode SE1, the second sub-electrode SE2 and the third sub-electrode SE3 may be electrically connected to the pixel driving circuit PD (showed in FIG. 3). The first sub-electrode SE1 may transmit a cathode voltage (or a low potential power voltage) from the pixel driving circuit PD (showed in FIG. 3) to the first light emitting device 130, the second sub-electrode SE2 may transmit the cathode voltage (or the low potential power voltage) from the pixel driving circuit PD (showed in FIG. 3) to the second light emitting device 140, and the third sub-electrode SE3 may transmit the cathode voltage (or the low potential power voltage) from the pixel driving circuit PD (showed in FIG. 3) to the third light emitting device 150.

The plurality of Tx electrodes Tx do not overlap (e.g., non-overlapping) the plurality of pixels PX and may surround the plurality of pixels PX. The plurality of Tx electrodes Tx may be disposed in an outer area of each of the plurality of pixels PX. In addition, the plurality of Tx electrodes Tx may be disposed between the sub-pixels SP adjacent to each other. In addition, each of the plurality of Tx electrodes Tx may be spaced apart from each other.

Each of the plurality of Tx electrodes Tx may include a plurality of opening areas OP. Each of the plurality of sub-electrodes SE may be disposed in the plurality of opening areas OP. One Tx electrode Tx may surround each of the plurality of sub-electrodes SE and may be spaced apart from the plurality of sub-electrodes SE. That is, an area of one sub-electrode SE may be smaller than an area of one open area OP. In addition, the plurality of Tx electrodes Tx may be disposed on the same layer as the plurality of sub-electrodes SE.

Due to the difference between the area of one sub-electrode SE and the area of one open area OP, a through hole TH may be disposed between the adjacent Tx electrode Tx and the sub-electrode SE. The through hole TH may surround the sub-electrode SE and the Tx electrode Tx may surround the through hole TH. In addition, the through hole TH may not overlap the light emitting device ED. Also, the through hole TH may overlap or may not overlap the signal line TL.

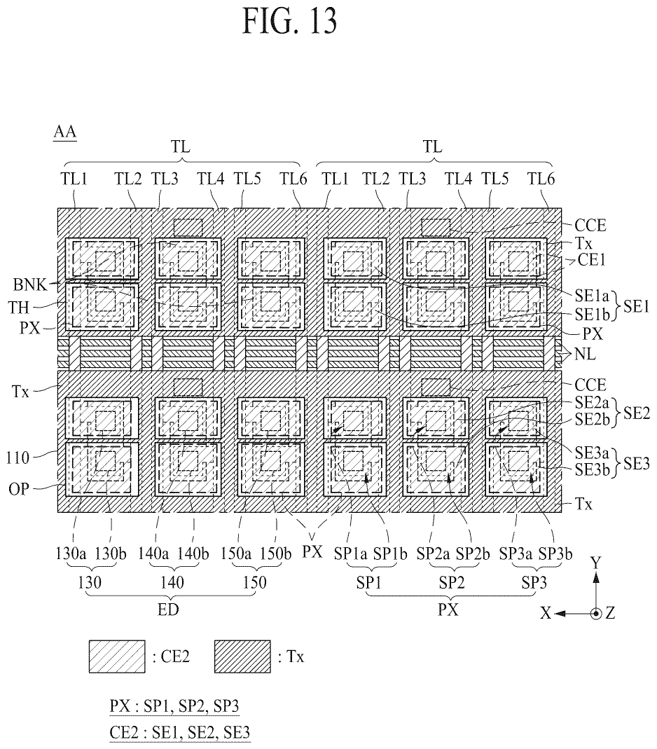

FIG. 13 is a plan view of a display area of a display device according to a third embodiment of the present disclosure.

Compared with the structure of the display area AA shown in FIG. 12, the display area AA shown in FIG. 13 includes the same configuration as the display area AA of FIG. 9 except for the structure of the plurality of second electrodes CE2 and the plurality of Tx electrodes Tx, and thus the description of the same configuration will be omitted.

As described above, one second electrode CE2 may include a plurality of sub-electrodes SE. Referring to FIG. 13, one second electrode CE2 may include a first sub-electrode SE1, a second sub-electrode SE2, and a third sub-electrode SE3.

The first sub-electrode SE1 may include a 1-1th sub-electrode SE1a disposed in the 1-1th sub-pixel SP1a and a 1-2th sub-electrode SE1b disposed in the 1-2th sub-pixel SP1b. The second sub-electrode SE2 may include a 2-1th sub-electrode SE2a disposed in the 2-1th sub-pixel SP2a and a 2-2th sub-electrode SE2b disposed in the 2-2th sub-pixel SP2b. The third sub-electrode SE3 may include a 3-1th sub-electrode SE3a disposed in the 3-1th sub-pixel SP3a and a 3-2-th sub-electrode SE1b disposed in the 3-2th sub-pixel SP3b. The 1-1th sub-electrode SE1a, the 1-2th sub-electrode SE1b, the 2-1th sub-electrode SE2b, the 3-1th sub-electrode SE3a, and the 3-2th sub-electrode SE3b may be spaced apart from each other.

The 1-1th sub-electrode SE1a may cover the 1-1th light emitting device 130a, and the 1-2th sub-electrode SE1b may cover the 1-2th light emitting device 130b. The 2-1th sub-electrode SE2a may cover the 2-1th light emitting device 140a, and the 2-2th sub-electrode SE2b may cover the 2-1th light emitting device 140b. The 3-1th sub-electrode SE3a may cover the 3-1th light emitting device 150a, and the 3-2th sub-electrode SE1b may cover the 3-1th light emitting device 150b.

Although not shown in FIG. 13, each of the 1-1th sub-electrode SE1a, the 1-2th sub-electrode SE1b, the 2-1th sub-electrode SE2a, the 2-1th sub-electrode SE2b, the 3-1th sub-electrode SE3a, and the 3-2th sub-electrode SE1b may be electrically connected to the pixel driving circuit PD (showed in FIG. 3).

The 1-1th sub-electrode SE1a may transmit the cathode voltage (or the low potential power voltage) from the pixel driving circuit PD (showed in FIG. 3) to the 1-1th light emitting device 130a, and the 1-2th sub-electrode SE1b may transmit the cathode voltage (or the low potential power voltage) from the pixel driving circuit PD (showed in FIG. 3) to the 1-2th light emitting device 130b. The 2-1th sub-electrode SE2a may transmit the cathode voltage (or the low potential power voltage) from the pixel driving circuit PD (showed in FIG. 3) to the 2-1th light emitting device 140a, and the 2-2th sub-electrode SE2b may transmit the cathode voltage (or the low potential power voltage) from the pixel driving circuit PD (showed in FIG. 3) to the 2-2th light emitting device 140b. The 3-1th sub-electrode SE3a may transmit the cathode voltage (or the low potential power voltage) from the pixel driving circuit PD (showed in FIG. 3) to the 3-1th light emitting device 150a, and the 3-2th sub-electrode SE3b may transmit the cathode voltage (or the low potential power voltage) from the pixel driving circuit PD (showed in FIG. 3) to the 3-2th light emitting device 150b.

As in FIG. 12, the plurality of Tx electrodes Tx do not overlap (e.g., non-overlapping) the plurality of pixels PX and may surround the plurality of pixels PX. The plurality of Tx electrodes Tx may be disposed in the outer area of each of the plurality of pixels PX. In addition, the plurality of Tx electrodes Tx may be disposed between the sub-pixels SP adjacent to each other. In addition, the plurality of Tx electrodes Tx may be disposed between the light emitting devices ED adjacent to each other. In addition, each of the plurality of Tx electrodes Tx may be spaced apart from each other.

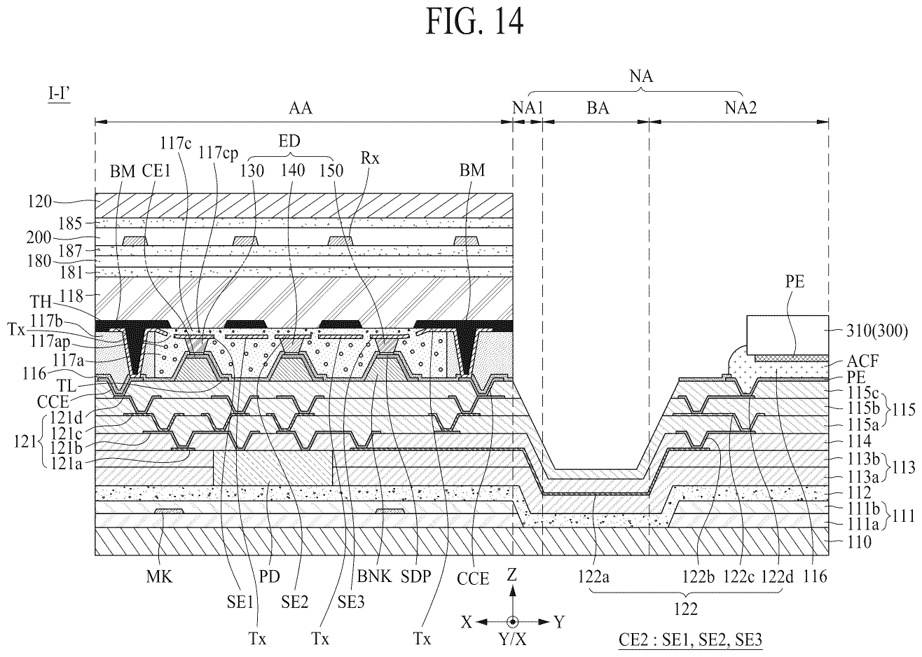

FIG. 14 is a cross-sectional view of a display device according to a second embodiment and a third embodiment of the present disclosure.

Compared with the structure of the display area AA shown in FIG. 10, the display area AA shown in FIG. 14 includes the same configuration as the display area AA of FIG. 10 except for the structure of the second electrode CE2, the Tx electrode Tx, and the Rx electrode Rx, and thus the description of the same configuration will be omitted.

Referring to FIG. 14, the second electrode CE2 may be disposed on the first optical layer 117a. The second electrode CE2 may include a first sub-electrode SE1, a second sub-electrode SE2 and a third sub-electrode SE3. Each of the first sub-electrode SE1, the second sub-electrode SE2, and the third sub-electrode SE3 may overlap the first optical layer 117a and may not overlap the second optical layer 117b. That is, ends of each of the first sub-electrode SE1, the second sub-electrode SE2, and the third sub-electrode SE3 may be disposed on the upper surface of the first optical layer 117a.

The second electrode CE2 may be disposed on the plurality of light emitting devices ED. The first sub-electrode SE1 may be in contact with the cathode 135 of the first light emitting device 130, the second sub-electrode SE2 may be in contact with the cathode 135 of the second light emitting device 140, and the third sub-electrode SE3 may be in contact with the cathode 135 of the third light emitting device 150. That is, the first sub-electrode SE1, the second sub-electrode SE2 and the third sub-electrode SE3 may be connected to different light emitting devices, respectively.

As described above, a region in which the first optical layer 117a is disposed may include a concave portion recessed from the upper surface of the second optical layer 117b. Since the first sub-electrode SE1, the second sub-electrode SE2 and the third sub-electrode SE3 are disposed on the upper surface of the first optical layer 117a, the first sub-electrode SE1, the second sub-electrode SE2 and the third sub-electrode SE3 may have a concave shape along the concave portion of the first optical layer 117a. That is, the first sub-electrode SE1, the second sub-electrode SE2 and the third sub-electrode SE3 may be disposed at a position lower than the second optical layer 117b.

The Tx electrode Tx may be disposed on the first optical layer 117a and the second optical layer 117b and may overlap the first optical layer 117a and the second optical layer 117b. Since a partial area of the Tx electrode Tx disposed on the first optical layer 117a is disposed along the concave portion, the partial area of the Tx electrode Tx disposed on the first optical layer 117a may be disposed at a position lower than the remaining portion of the Tx electrode Tx disposed on the second optical layer 117b.

A partial area of the Tx electrode Tx may be disposed between the first sub-electrode SE1 and the second sub-electrode SE2, and another partial area of the Tx electrode Tx may be disposed between the second sub-electrode SE2 and the third sub-electrode SE3.

A through hole TH may be disposed between the first sub-electrode SE1 and the Tx electrode Tx, between the second sub-electrode SE2 and the Tx electrode Tx, and between the third sub-electrode SE3 and the Tx electrode Tx. Each of the first sub-electrode SE1, the second sub-electrode SE2, and the third sub-electrode SE3 may be spaced apart from the Tx electrode Tx by the through hole TH. The through hole TH may overlap the first optical layer 117a.

A third optical layer 117c may be disposed on the first sub-electrode SE1, the second sub-electrode SE2, the third sub-electrode SE3, and the Tx electrode Tx. The third optical layer 117c may fill an inside of the through hole TH.

In the display area AA, a black matrix BM may be disposed on the Tx electrode Tx, the first optical layer 117a, the second optical layer 117b, and the third optical layer 117c. The black matrix BM may overlap the Tx electrode Tx. The black matrix BM may not overlap each of the first sub-electrode SE1, the second sub-electrode SE2 and the third sub-electrode SE3.

An insulating layer 200 may include an Rx electrode Rx. The Rx electrode Rx overlaps the black matrix BM, and may not overlap the light emitting device ED. In addition, the Rx electrode Rx may overlap the Tx electrode Tx. That is, the Rx electrode Rx may be disposed between the light emitting devices ED adjacent to each other.

As described in FIG. 10, the present disclosure discloses a use of a metal layer provided on the same layer as the second electrode CE2 as the Tx electrode Tx. Accordingly, only the Rx electrode Rx is additionally formed on the second electrode CE2, and a touch may be detected using an insulating layer such as a cover layer 118 disposed between the second electrode CE2 and the Rx electrode Rx as a touch insulating layer.

Meanwhile, FIG. 14 shows that the second electrode CE2 includes a plurality of sub-electrodes SE, so that Tx electrodes Tx are additionally formed not only in the outer area of the pixel PX but also in area between the light emitting devices ED adjacent to each other. Accordingly, by increasing the number of the Tx electrodes Tx and Rx electrodes Rx, an accuracy of touch detection may be improved.

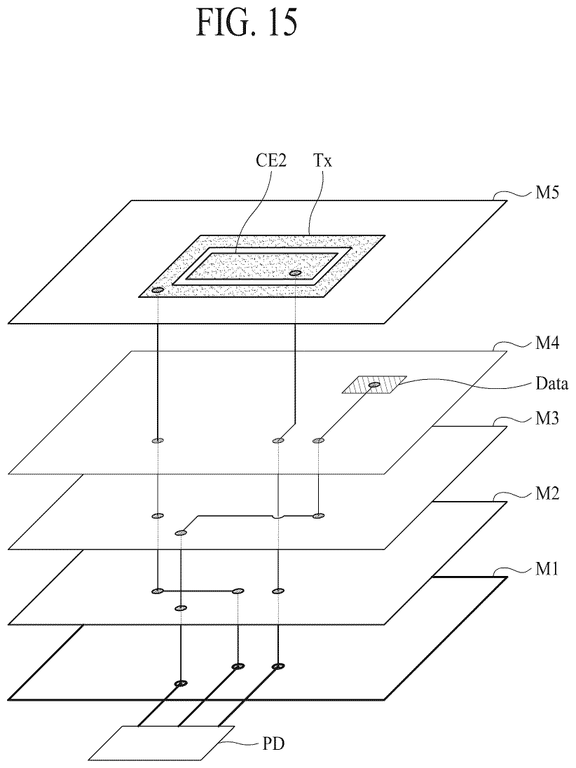

FIG. 15 is a configuration diagram of a wiring of a display device according to an embodiment of the present disclosure.

Referring to FIG. 15, the pixel driving circuit PD, the second electrode CE2, and the Tx electrode Tx may be electrically connected through a plurality of metal layers M.

The plurality of metal layers M may include a first metal layer M1, a second metal layer M2, a third metal layer M3, a fourth metal layer M4, and a fifth metal layer M.

The first metal layer M1 may be disposed on the pixel driving circuit PD. The first metal layer M1 may include a 1-1th connection line 121a. The 1-1th connection line 121a may be electrically connected to the pixel driving circuit PD.

The second metal layer M2 may be disposed on the first metal layer M1. The second metal layer M2 may include a plurality of 1-2th connection lines 121b. The plurality of 1-2th connection lines 121b may be electrically connected to the 1-1th connection lines 121a.

The third metal layer M3 may be disposed on the second metal layer M2. The third metal layer M3 may include a plurality of 1-3th connection lines 121c. The plurality of 1-3 connection lines 121c may be electrically connected to the plurality of 1-2th connection lines 121b.

The fourth metal layer M4 may be disposed on the third metal layer M3. The fourth metal layer M4 may include a plurality of 1-4th connection lines 121d. Some of the plurality of 1-4th connection lines 121d may be electrically connected to the plurality of 1-3th connection lines 121c. In addition, some of the plurality of 1-4th connection lines 121d may be electrically connected to a data line Data.

The fifth metal layer M5 may be disposed on the fourth metal layer M4. The fifth metal layer M5 may include a second electrode CE and a Tx electrode Tx. Each of the second electrode CE and the Tx electrode Tx may be electrically connected to the plurality of 1-4th connection lines 121d.

That is, each of the second electrode CE and the Tx electrode Tx may be electrically connected to the pixel driving circuit PD through the 1-1th connection line 121a, the 1-2th connection line 121b, the 1-3th connection line 121c, and the 1-4th connection line 121d. Accordingly, the second electrode CE may receive a cathode voltage from the pixel driving circuit PD, and the Tx electrode Tx may receive a touch driving signal.

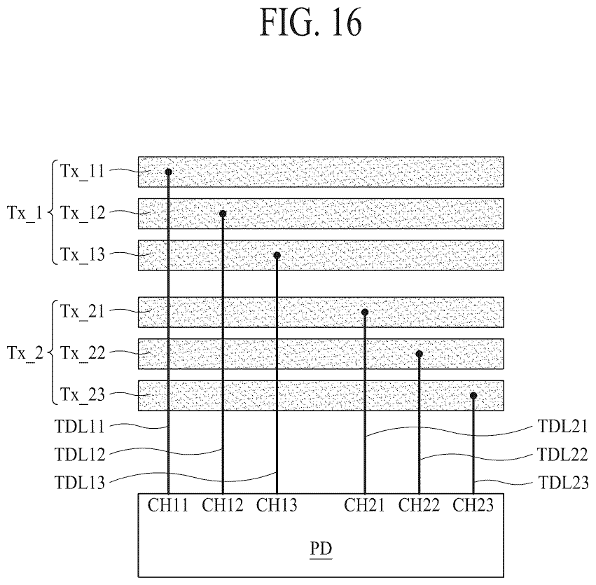

FIG. 16 is a block diagram of a Tx electrode Tx according to a first embodiment of the present disclosure.

As described above, the plurality of Tx electrodes Tx may be electrically connected to the pixel driving circuit PD through the 1-1th connection line 121a, the 1-2th connection line 121b, the 1-3th connection line 121c, and the 1-4th connection line 121d. In FIG. 16, paths of the 1-1th connection line 121a, the 1-2th connection line 121b, the 1-3th connection line 121c, and the 1-4th connection line 121d for applying a touch driving signal to the plurality of Tx electrodes Tx are specified as a touch driving line TDL.

As described in FIG. 16, the first Tx electrode Tx_1 may include a 1-1th Tx electrode Tx_11, a 1-2th Tx electrode Tx_12, and a 1-3th Tx electrode Tx_13. Also, the second Tx electrode Tx_2 may include a 2-1th Tx electrode Tx_21, a 2-1th Tx electrode Tx_22, and a 2-3th Tx electrode Tx_23.

The touch driving line TDL may include a 1-1th touch driving line TDL11, a 1-2th touch driving line TDL12, a 1-3th touch driving line TDL13, a 2-1th touch driving line TDL21, a 2-2th touch driving line TDL22, and a 2-3th touch driving line TDL23.

The 1-1th touch driving line TDL11 may connect a 1-1th channel CH11 of the pixel driving circuit PD to the 1-1th Tx electrode Tx_11. The 1-2th touch driving line TDL12 may connect a 1-2 channel CH12 of the pixel driving circuit PD to the 1-2th Tx electrode Tx_12. The 1-3th touch driving line TDL13 may connect a 1-3 channel CH13 of the pixel driving circuit PD to the 1-3th Tx electrode Tx_13. The 2-1th touch driving line TDL21 may connect a 2-1 channel CH21 of the pixel driving circuit PD to the 2-1th Tx electrode Tx_21. The 2-2th touch driving line TDL22 may connect a 2 -2 channel CH22 of the pixel driving circuit PD to the 2-2th Tx electrode Tx_22. The 2-3th touch driving line TDL23 may connect a 2-3 channel CH23 of the pixel driving circuit PD to the 2-3th Tx electrode Tx_23.

That is, the pixel driving circuit PD may apply the touch driving signal to each of the 1-1th Tx electrode Tx_11, the 1-2th Tx electrode Tx_12, the 1-2th Tx electrode Tx_13, the 2-1th Tx electrode Tx_21, the 2-1th Tx electrode Tx_22, and the 2-3th Tx electrode Tx_23, through different touch driving lines TDL.

The pixel driving circuit PD may apply the same touch driving signal to the 1-1th Tx electrode Tx_11, the 1-2th Tx electrode Tx_12, and the 1-3th Tx electrode Tx_13, and apply the same touch driving signal to the 2-1th Tx electrode Tx_21, the 2-1th Tx electrode Tx_22, and the 2-3th Tx electrode Tx_23. That is, each of the first Tx electrode Tx_1 and the second Tx electrode Tx_2 may include a plurality of electrodes receiving the same signal. Accordingly, an area of the Tx electrode Tx receiving the same signal is increased so that the signal may be stably applied.

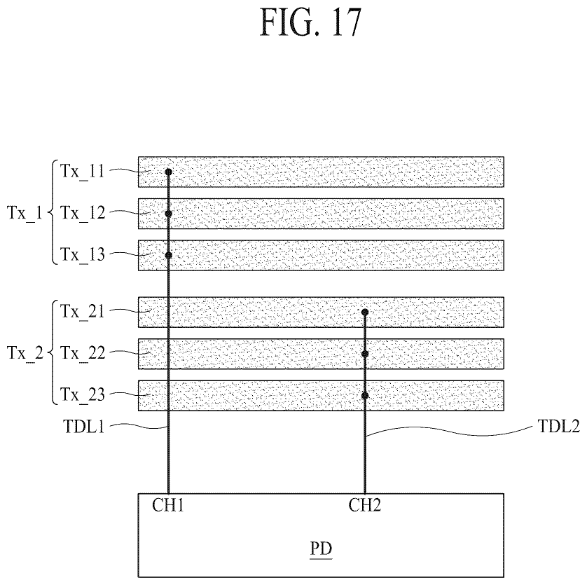

FIG. 17 is a block diagram of a Tx electrode according to a second embodiment of the present disclosure.

Compared with FIG. 16, the block diagram of the Tx electrode Tx shown in FIG. 17 includes the same configuration as that of FIG. 16 except for the structure of the touch driving line TDL and the channel CH of the pixel driving circuit PD, so the description of the same configuration will be omitted.

Referring to FIG. 17, a touch driving line TDL may include a first touch driving line TDL1 and a second touch driving line TDL2. The first touch driving line TDL1 may simultaneously connect a first channel CH1 of the pixel driving circuit PD to a 1-1th Tx electrode Tx_11, a 1-2th Tx electrode Tx_12, and a 1-2th Tx electrode Tx_13. The second touch driving line TDL2 may simultaneously connect a second channel CH2 of the pixel driving circuit PD to a 2-1th Tx electrode Tx_21, a 2-1th Tx electrode Tx_22, and a 2-3th Tx electrode Tx_23.

That is, the pixel driving circuit PD may apply the same touch driving signal to the 1-1th Tx electrode Tx_11, the 1-2th Tx electrode Tx_12, and the 1-3th Tx electrode Tx_13, through one touch driving line TDL. In addition, the pixel driving circuit PD may apply the same touch driving signal to the 2-1th Tx electrode Tx_21, the 2-1th Tx electrode Tx_22, and the 2-3th Tx electrode Tx_23, through one touch driving line TDL. Accordingly, the number of wirings may be reduced while increasing an area of the Tx electrode Tx receiving the same signal.

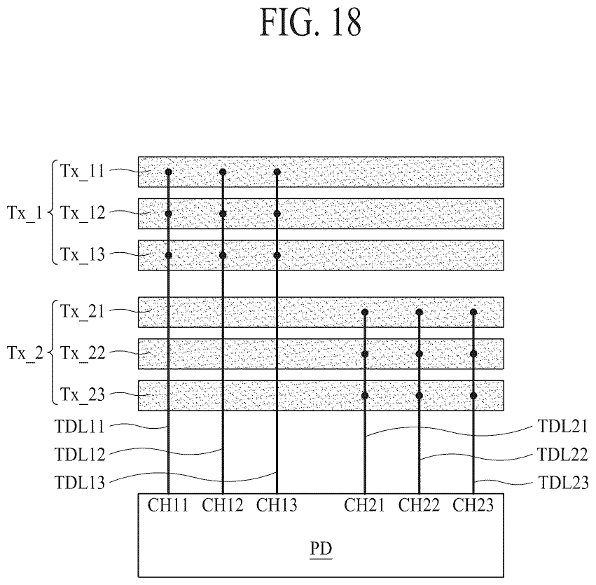

FIG. 18 is a block diagram of a Tx electrode according to a third embodiment of the present disclosure.

Referring to FIG. 18, a touch driving line TDL may include a 1-1th touch driving line TDL11, a 1-2th touch driving line TDL12, a 1-3th touch driving line TDL13, a 2-1th touch driving line TDL21, a 2-2th touch driving line TDL22, and a 2-3th touch driving line TDL23.

The 1-1th touch driving line TDL11 may simultaneously connect a 1-1th channel CH11 of the pixel driving circuit PD to the 1-1th Tx electrode Tx_11, the 1-2th Tx electrode Tx_12, and the 1-3th Tx electrode Tx_13. The 1-2th touch driving line TDL12 may simultaneously connect a 1-2th channel CH12 of the pixel driving circuit PD to the 1 -1 Tx_11, the 1-2th Tx electrode Tx_12, and the 1-3th Tx electrode Tx_13. The 1-3th touch driving line TDL13 may simultaneously connect a 1-3th channel CH13 of the pixel driving circuit PD to the 1-1th Tx electrode Tx_11, the 1-2th Tx electrode Tx_12, and the 1-3th Tx electrode Tx_13.

The 2-1th touch driving line TDL21 may simultaneously connect a 2-1th channel CH21 of the pixel driving circuit PD to the 2-1th Tx electrode Tx_21, the 2-2th Tx electrode Tx_22, and the 2-3th Tx electrode Tx_23. The 2-2th touch driving line TDL22 may simultaneously connect a 2-2th channel CH22 of the pixel driving circuit PD to the 2-1 Tx_21, the 2-2th Tx electrode Tx_22, and the 2-3th Tx electrode Tx_23. The 2-3th touch driving line TDL23 may simultaneously connect a 2-3th channel CH23 of the pixel driving circuit PD to the 2-1th Tx electrode Tx_21, the 2-2th Tx electrode Tx_22, and the 2-3th Tx electrode Tx_23.

That is, one Tx electrode Tx may be connected to the plurality of touch driving lines TDL. Accordingly, even if a defect occurs in any one touch driving line TDL, the Tx electrode Tx may be normally driven. In addition, since the plurality of touch driving lines TDL are arranged in parallel, resistance between the plurality of touch driving lines TDL may be reduced.

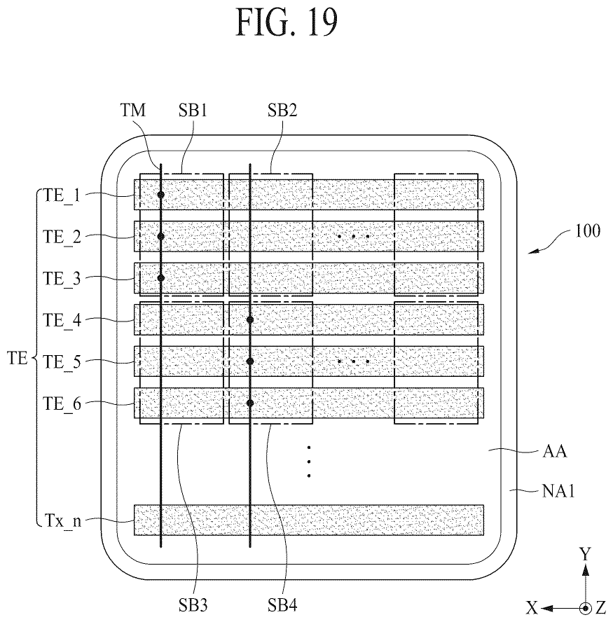

FIG. 19 is a plan view of a display device according to another embodiment of the present disclosure. In particular, in FIG. 5, a touch electrode structure in a mutual-capacitance type is disclosed, while in FIG. 19, a touch electrode structure in a self-capacitance type is disclosed.

In FIG. 5, the plurality of Tx electrodes Tx and the plurality of Rx electrodes Rx are disclosed, but in FIG. 19, only a plurality of touch electrodes TE are disclosed.

Referring to FIG. 19, the display device may include a plurality of touch electrodes TE. The plurality of touch electrodes TE may extend along the column direction (or the first direction X) and may be spaced apart along the row direction (or the second direction Y).

The plurality of touch electrodes TE may receive a touch driving signal and a touch sensing signal. Accordingly, the touch driving signal may be applied to one or more touch electrodes TE, and the sensing signal may be received from the touch electrode TE to which the touch driving signal is applied to sense a change in capacitance between the touch electrode TE and the user's finger or tool. Therefore, a presence or absence of a touch and a position of the touch position may be detected.

In this case, a plurality of sensing blocks SB may be configured by the plurality of touch electrodes TE. Each of the plurality of sensing blocks SB may be a basic unit for detecting a touch by a user's finger or tool.

For example, the plurality of sensing blocks SB may include a first sensing block SB1, a second sensing block SB2, a third sensing block SB3 and a fourth sensing block SB4. Each of the first sensing block SB1 and the second sensing block SB2 may include a first touch electrode TE_1, a second touch electrode TE_2, and a third touch electrode TE_3. In addition, each of the third sensing block SB3 and the fourth sensing block SB4 may include a fourth touch electrode TE_4, a fifth touch electrode TE_5, and a sixth touch electrode TE_6. That is, the plurality of sensing blocks SB may be configured by the same touch electrode TE. In addition, FIG. 19 illustrates configuration of one sensing block SB by three touch electrodes TE, but the present disclosure is not limited thereto.

The plurality of touch electrodes TE constituting one sensing block SB may be electrically connected to each other by a touch metal layer TM. For example, the first touch electrode TE_1, the second touch electrode TE_2, and the third touch electrode TE_3 may be electrically connected to each other by any one touch metal layer TM. In addition, the fourth touch electrode TE_4, the fifth touch electrode TE_5, and the sixth touch electrode TE_6 may be electrically connected to each other by any one touch metal layer TM. Accordingly, by configuring the sensing block SB using the plurality of touch electrodes TE, an area of the sensing block SB may be increased to stably apply a signal.

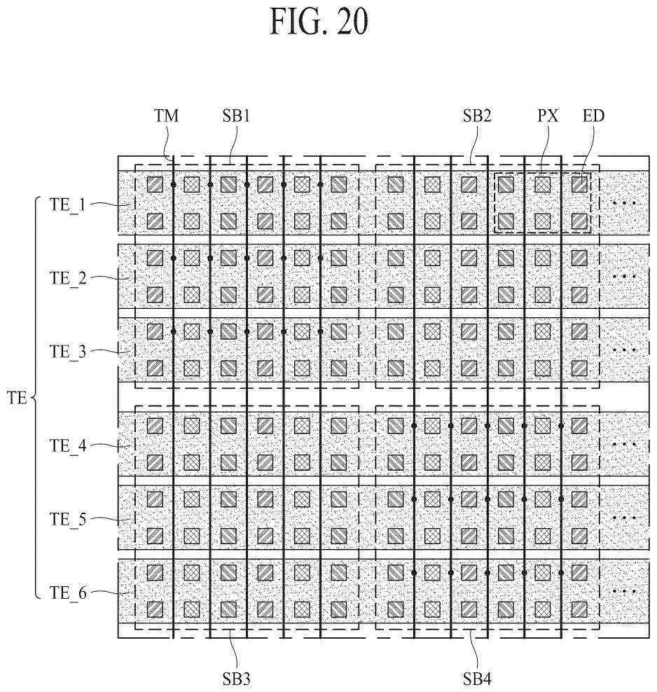

FIG. 20 is an enlarged view of a partial area of FIG. 19. In detail, a partial area in which first to sixth touch electrodes TE1 to TE6 are disposed among a plurality of touch electrodes TE is illustrated.

Referring to FIG. 20, each of the first to sixth touch electrodes TE1 to TE6 may extend along the column direction (or the first direction X) and may be spaced apart along the row direction (or the second direction Y).

A plurality of pixels PX may be disposed under the plurality of touch electrodes TE. Each of the plurality of pixels PX may include a plurality of light emitting devices ED.

As described above, the plurality of touch electrodes TE constituting one sensing block SB may be electrically connected to each other by the touch metal layer TM. The touch metal layer TM may be disposed between the light emitting devices ED adjacent to each other in one-pixel PX. Referring to FIG. 20, the first to third touch electrodes TE1 to TE3 may be electrically connected to each other by the plurality of touch metal layers TM. In addition, the fourth to sixth touch electrodes TE4-TE6 may be electrically connected to each other by the plurality of touch metal layers TM.

The plurality of touch electrodes TE and second electrodes CE may correspond to shapes of the plurality of Tx electrodes Tx and second electrodes CE according to FIGS. 9, 12, and 13.

For example, as in FIG. 9, the plurality of touch electrodes TE may be disposed on the plurality of pixels PX and may be disposed on the light emitting device ED. In addition, each of the plurality of touch electrodes TE may include a plurality of opening areas OP. Each of the plurality of second electrodes CE2 may be disposed in the plurality of opening areas OP. Due to a difference between an area of one second electrode CE2 and an area of one opening area OP, a through hole TH may be disposed between the touch electrodes TE and the second electrode CE2 adjacent to each other.

In addition, as in FIG. 12, one second electrode CE2 may include a first sub-electrode SE1, a second sub-electrode SE2, and a third sub-electrode SE3. Each of the plurality of touch electrodes TE may include a plurality of opening areas OP. Each of the plurality of sub-electrodes SE may be disposed in the plurality of opening areas OP. Due to a difference between an area of one sub-electrode SE and an area of one opening area OP, a through hole TH may be disposed between the adjacent touch electrode TE and the sub-electrode SE.

In addition, as in FIG. 13, the one second electrode CE2 may include a first sub-electrode SE1, a second sub-electrode SE2 and a third sub-electrode SE3. The first sub-electrode SE1 includes a 1-1th sub-electrode SE1a and a 1-2th sub-electrode SE1b, the second sub-electrode SE2 includes a 2-1th sub-electrode SE2a and a 2-2th sub-electrode SE2b, and the third sub-electrode SE3 may include a 3-1th sub-electrode SE3a and a 3-2th sub-electrode SE1b.

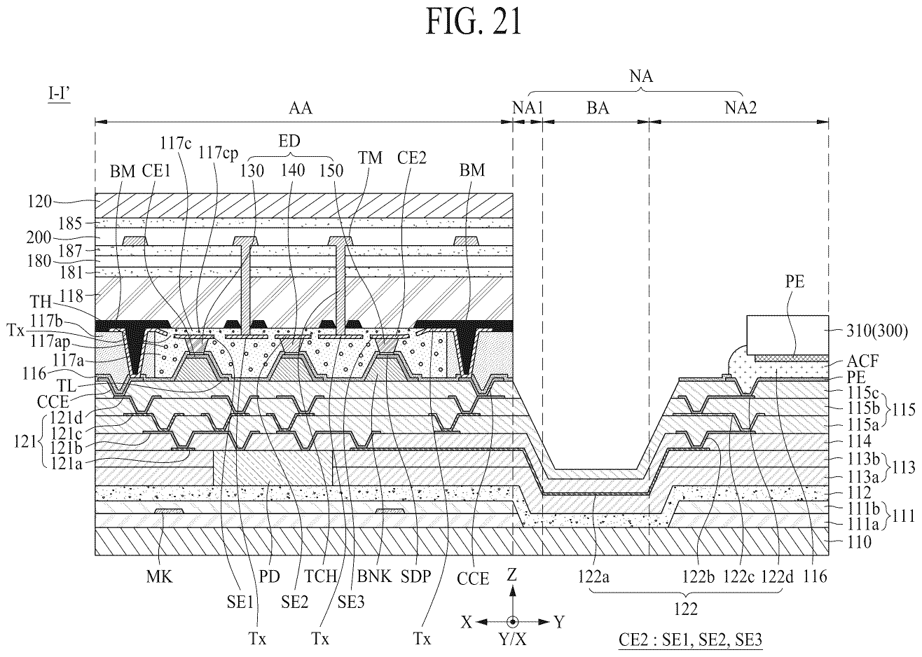

FIG. 21 is a cross-sectional view of a display device according to an embodiment of the present disclosure.

Compared to the structure of the display area AA shown in FIG. 14, the display area AA shown in FIG. 21 includes the same configuration as the display area AA of FIG. 14 except for the structure of the touch electrode TE and the touch metal layer TM, so the description of the same configuration will be omitted.

Referring to FIG. 21, the second electrode CE may be disposed on a first optical layer 117a. The second electrode CE may include a first sub-electrode SE1, a second sub-electrode SE2 and a third sub-electrode SE3. Each of the first sub-electrode SE1, the second sub-electrode SE2, and the third sub-electrode SE3 may overlap the first optical layer 117a and may not overlap a second optical layer 117b. That is, ends of each of the first sub-electrode SE1, the second sub-electrode SE2, and the third sub-electrode SE3 may be disposed on an upper surface of the first optical layer 117a.

The second electrode CE2 may be disposed on a plurality of light emitting devices ED. The first sub-electrode SE1 may be in contact with a cathode 135 of the first light emitting device 130, the second sub-electrode SE2 may be in contact with a cathode 135 of the second light emitting device 140, and the third sub-electrode SE3 may be in contact with a cathode 135 of the third light emitting device 150. That is, each of the first sub-electrode SE1, the second sub-electrode SE2 and the third sub-electrode SE3 may be connected to a different light emitting device.

As described above, a region in which the first optical layer 117a is disposed may include a concave portion recessed from an upper surface of the second optical layer 117b. Since the first sub-electrode SE1, the second sub-electrode SE2 and the third sub-electrode SE3 are disposed on the upper surface of the first optical layer 117a, the first sub-electrode SE1, the second sub-electrode SE2 and the third sub-electrode SE3 may have a concave shape along the concave portion of the first optical layer 117a. That is, the first sub-electrode SE1, the second sub-electrode SE2 and the third sub-electrode SE3 may be disposed at a position lower than the second optical layer 117b.

The touch electrode TE may be disposed on the first optical layer 117a and the second optical layer 117b and may overlap the first optical layer 117a and the second optical layer 117b. Since a partial area of the touch electrode TE disposed on the first optical layer 117a is disposed along the concave portion, the partial area of the touch electrode TE disposed on the first optical layer 117a may be disposed at a position lower than the remaining portion of the touch electrode TE disposed on the second optical layer 117b.

A partial area of the touch electrode TE may be disposed between the first sub-electrode SE1 and the second sub-electrode SE2, and another partial area may be disposed between the second sub-electrode SE2 and the third sub-electrode SE3.

A through hole TH may be disposed between the first sub-electrode SE1 and the touch electrode TE, between the second sub-electrode SE2 and the touch electrode TE, and between the third sub-electrode SE3 and the touch electrode TE. The first sub-electrode SE1, the second sub-electrode SE2, and the third sub-electrode SE3 may be spaced apart from each other by the through hole TH. The through hole TH may overlap the first optical layer 117a.

A third optical layer 117c may be disposed on the first sub-electrode SE1, the second sub-electrode SE2, the third sub-electrode SE3, and the touch electrode TE. The third optical layer 117c may fill an inside of the through hole TH.

A black matrix BM may be disposed on the touch electrode TE, the first optical layer 117a, the second optical layer 117b, and the third optical layer 117c in the display area AA. The black matrix BM may overlap the touch electrode TE. The black matrix BM may not overlap each of the first sub-electrode SE1, the second sub-electrode SE2, and the third sub-electrode SE3.

An insulating layer 200 may include a touch metal layer TM. The touch metal layer TM overlaps the black matrix BM, and may not overlap the light emitting device ED. Also, the touch metal layer TM may overlap the touch electrode TE. That is, the touch metal layer TM may be disposed between the light emitting devices ED adjacent to each other.

The touch metal layer TM may be electrically connected to the touch electrode TE through a touch contact hole TCH. The touch contact hole TCH may penetrate the black matrix BM and the third optical layer 117c. FIG. 21 illustrates that the touch contact hole TCH is disposed in an area between the first light emitting device 130 and the second light emitting device 140 and an area between the second light emitting device 140 and the third light emitting device 150, but the present disclosure is not limited thereto.

Generally, a touch panel in a self-capacitance type discloses a touch electrode, a wiring layer for configuring a sensing block, and a touch insulating layer disposed between the touch electrode and the wiring layer. However, the present disclosure discloses to use a metal layer disposed on the same layer as the second electrode CE2 and disposed an outer area of the pixel PX and an area between the light emitting devices ED adjacent to each other as the touch electrode TE. Accordingly, only the touch metal layer TM may be additionally formed on the second electrode CE2 to detect a touch. Therefore, it is possible to reduce a thickness of the display device and simplify a manufacture process.

In FIG. 21, the metal layer disposed on the same layer as the second electrode CE2 and disposed an outer area of the pixel PX and an area between the light emitting devices ED adjacent to each other is used as the touch electrode TE. And, in FIG. 21, the touch metal layer TM is formed on the touch electrode TE, but the present disclosure is not limited thereto. For example, the metal layer disposed on the same layer as the second electrode CE2 and disposed an outer area of the pixel PX and an area between the light emitting devices ED adjacent to each other may be used as the touch metal layer TM, and the touch electrode TE may be formed on the touch metal layer TM.

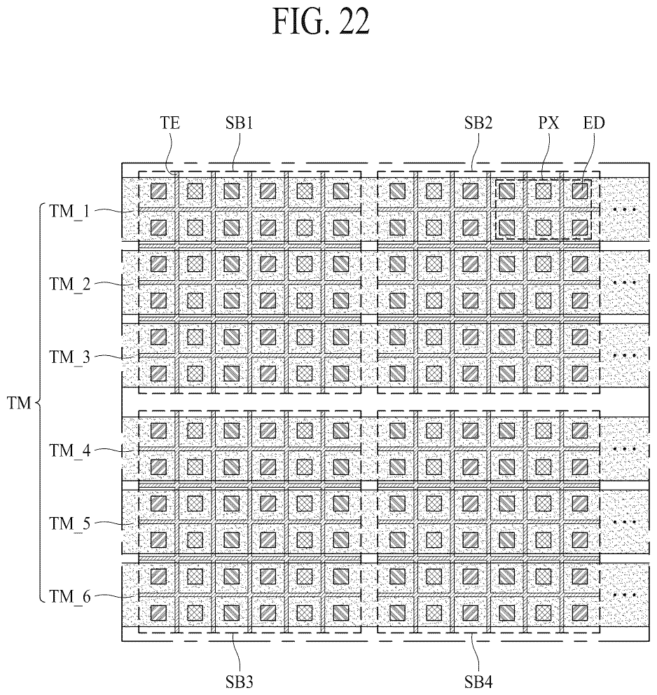

In this case, as shown in FIG. 22, the plurality of touch electrodes TE may be disposed in each of the plurality of sensing blocks SB and may have a mesh structure. That is, one touch electrode TE may be disposed in one sensing block SB. In addition, each of the touch electrodes TE may be disposed between the light emitting devices ED adjacent to each other. In addition, as shown in FIG. 21, the touch electrode TE and the touch metal layer TM may be electrically connected through the touch contact hole TCH.

The plurality of touch electrodes TE and the second electrode CE may correspond to the connection structure of the plurality of Tx electrodes Tx, the second electrode CE and the pixel driving circuit PD disclosed in FIG. 15.

For example, as in FIG. 15, the pixel driving circuit PD, the plurality of touch electrodes TE and the second electrode CE may be electrically connected through a plurality of metal layers M.

As described in FIG. 15, the plurality of metal layers M may include a first metal layer M1, a second metal layer M2, a third metal layer M3, a fourth metal layer M4, and a fifth metal layer M5. In this case, the fifth metal layer M5 may include a second electrode CE and a touch electrode TE.

Each of the second electrode CE and the touch electrode TE may be electrically connected to the pixel driving circuit PD through the 1-1th connection line 121a of the first metal layer M1, the 1-2th connection line 121b of the second metal layer M2, the 1-3th connection line 121c of the third metal layer M3, and the 1-4th connection line 121d of the fourth metal layer M4. Accordingly, the second electrode CE may receive a cathode voltage from the pixel driving circuit PD, and the touch electrode TE may receive a touch driving signal.

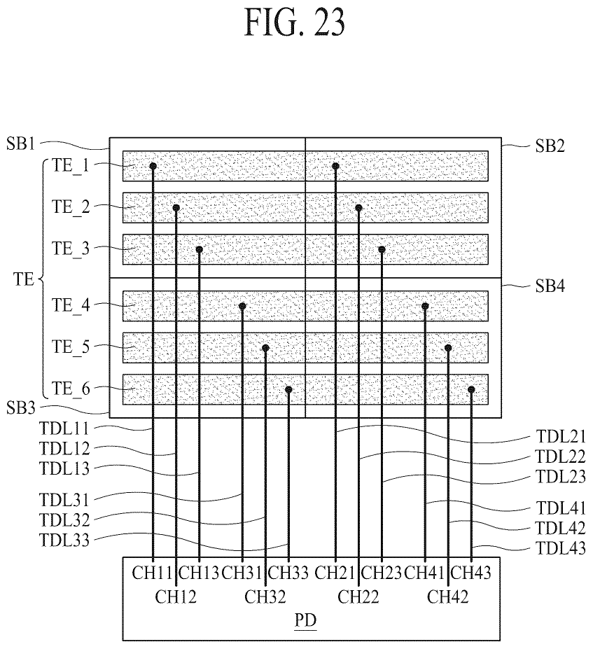

FIG. 23 is a block diagram of a touch electrode according to a first embodiment of the present disclosure.

As described above, the plurality of touch electrodes TE may be electrically connected to the pixel driving circuit PD through the 1-1th connection line 121a, the 1-2th connection line 121b, the 1-3th connection line 121c, and the 1-4th connection line 121d. In FIG. 23, a path of the 1-1th connection line 121a, the 1-2th connection line 121b, the 1-3th connection line 121c, and the 1-4th connection line 121d for the pixel driving circuit PD to apply the touch driving signal to the plurality of touch electrodes TE is specified as a touch driving line TDL.

As described in FIGS. 19 and 20, the plurality of touch electrodes TE may include first to sixth touch electrodes TE1 to TE6. In addition, the plurality of sensing blocks SB composed of at least one of the first to sixth touch electrodes TE1 to TE6 are disclosed. The sensing block SB may include a first sensing block SB1, a second sensing block SB2, a third sensing block SB3 and a fourth sensing block SB4.

The pixel driving circuit PD may apply the touch driving signal to the first sensing block SB1 through a 1-1th touch driving line TDL11, a 1-2th touch driving line TDL12, and a 1-3th touch driving line TDL13.

The 1-1th touch driving line TDL11 may connect a 1-1th channel CH11 of the pixel driving circuit PD and the first touch electrode TE_1. The 1-2th touch driving line TDL12 may connect a 1-2th channel CH12 of the pixel driving circuit PD and the second touch electrode TE_2. The 1-3th touch driving line TDL13 may connect a 1-3th channel CH13 of the pixel driving circuit PD and the third touch electrode TE_3.

The pixel driving circuit PD may apply the touch driving signal to the second sensing block SB2 through a 2-1th touch driving line TDL21, a 2-2th touch driving line TDL22, and a 2-3th touch driving line TDL23.

The 2-1th touch driving line TDL21 may connect a 2-1th channel CH21 of the pixel driving circuit PD to the first touch electrode TE_1. The 2-2th touch driving line TDL22 may connect a 2-2th channel CH22 of the pixel driving circuit PD to the second touch electrode TE_2. The 2-3th touch driving line TDL23 may connect a 2-3th channel CH23 of the pixel driving circuit PD to the third touch electrode TE_3.

That is, according to the applied touch driving signal, the first touch electrode TE_1, the second touch electrode TE_2, and the third touch electrode TE_3 may function as the first sensing block SB1 or the second sensing block SB2.

The pixel driving circuit PD may apply the touch driving signal to the third sensing block SB3 through a 3-1th touch driving line TDL31, a 3-2th touch driving line TDL32, and a 3-3th touch driving line TDL33.

The 3-1th touch driving line TDL31 may connect a 3-1th channel CH31 of the pixel driving circuit PD to the fourth touch electrode TE_4. The 3-2th touch driving line TDL32 may connect a 3-2th channel CH32 of the pixel driving circuit PD to the fifth touch electrode TE_5. The 3-3th touch driving line TDL33 may connect a 3-3th channel CH33 of the pixel driving circuit PD to the sixth touch electrode TE_6.

The pixel driving circuit PD may apply the touch driving signal to the fourth sensing block SB4 through a 4-1th touch driving line TDL41, a 4-2th touch driving line TDL42, and a 4-3th touch driving line TDL43.

The 4-1th touch driving line TDL41 may connect a 4-1th channel CH41 of the pixel driving circuit PD to the fourth touch electrode TE_4. The 4-2th touch driving line TDL42 may connect a 4-2th channel CH42 of the pixel driving circuit PD to the fifth touch electrode TE_5 The 4-3th touch driving line TDL43 may connect a 4-3th channel CH43 of the pixel driving circuit PD to the sixth touch electrode TE_6.

That is, according to the applied touch driving signal, the fourth touch electrode TE_4, the fifth touch electrode TE_5, and the sixth touch electrode TE_6 may function as the third sensing block SB3 or the fourth sensing block SB4.

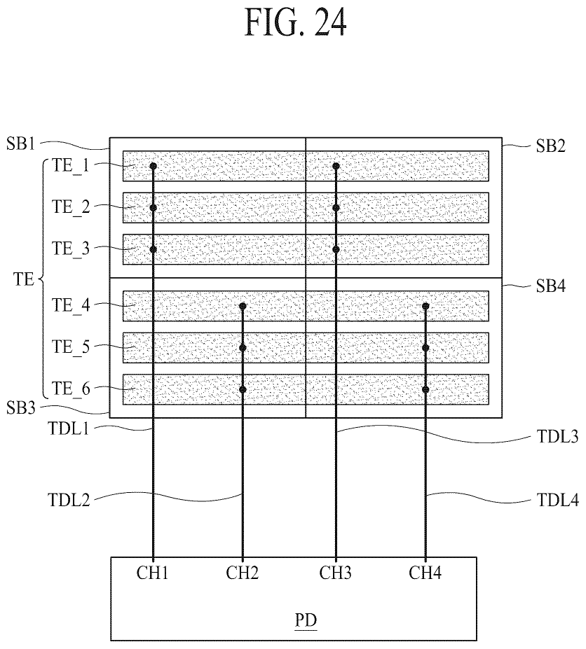

FIG. 24 is a block diagram of a touch electrode according to a second embodiment of the present disclosure.

Compared with FIG. 23, the block diagram of the touch electrode TE shown in FIG. 24 includes the same configuration as that of FIG. 23 except for the structure of the touch driving line TDL and the channel CH of the pixel driving circuit PD, and thus the description of the same configuration will be omitted.

Referring to FIG. 24, the touch driving line TDL may include a first touch driving line TDL1, a second touch driving line TDL2, a third touch driving line TDL3, and a fourth touch driving line TDLA. The first touch driving line TDL1 may simultaneously connect the first channel CH1 of the pixel driving circuit PD to the first touch electrode TE1, the second touch electrode TE2 and the third touch electrode TE3 constituting the first sensing block SB1. The second touch driving line TDL2 may simultaneously connect the second channel CH2 of the pixel driving circuit PD to the first touch electrode TE1, the second touch electrode TE2 and the third touch electrode TE3 constituting the second sensing block SB2. The third touch driving line TDL3 may simultaneously connect the third channel CH3 of the pixel driving circuit PD to the fourth touch electrode TE4, the fifth touch electrode TE5 and the sixth touch electrode TE6 constituting the third sensing block SB3. The fourth touch driving line TDL4 may simultaneously connect the fourth channel CH4 of the pixel driving circuit PD to the fourth touch electrode TE4, the fifth touch electrode TE5 and the sixth touch electrode TE6 constituting the fourth sensing block SB4.

That is, the pixel driving circuit PD may apply the same touch driving signal to the plurality of touch electrodes TE constituting one sensing block SB through one touch driving line TDL. Accordingly, the number of wires may be reduced while increasing an area of the touch electrodes TE receiving the same signal.

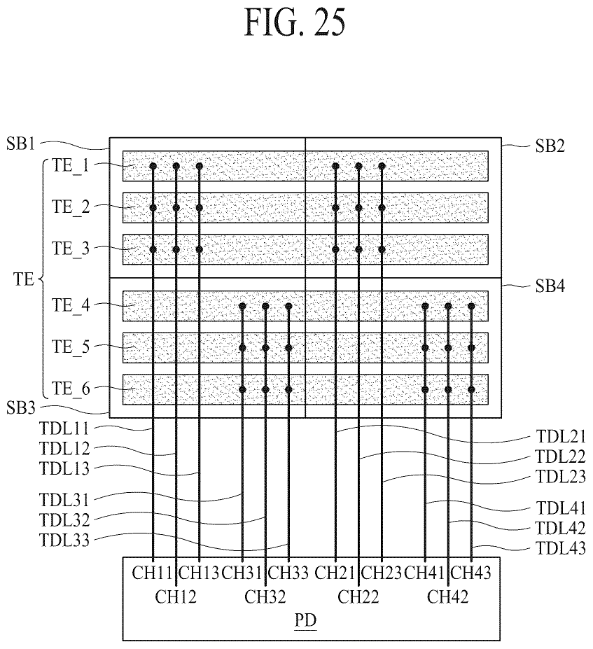

FIG. 25 is a block diagram of a touch electrode according to a third embodiment of the present disclosure.

Referring to FIG. 25, the 1-1th touch driving line TDL11 may simultaneously connect the 1-1th channel CH11 of the pixel driving circuit PD to the first to third touch electrodes TE1 to TE3. The 1-2th touch driving line TDL12 may simultaneously connect the 1-2th channel CH12 of the pixel driving circuit PD to the first to third touch electrodes TE1 to TE3. The 1-3th touch driving line TDL13 may simultaneously connect the 1-3th channels CH13 of the pixel driving circuit PD to the first to third touch electrodes TE1 to TE3.

The 2-1th touch driving line TDL21 may simultaneously connect the 2-1th channel CH21 of the pixel driving circuit PD and the first to third touch electrodes TE1 to TE3. The 2-2th touch driving line TDL22 may simultaneously connect the 2-2th channel CH22 of the pixel driving circuit PD and the first to third touch electrodes TE1 to TE3. The 2-3th touch driving line TDL23 may simultaneously connect the 2-3th channel CH23 of the pixel driving circuit PD and the first to third touch electrodes TE1 to TE3.

The 3-1th touch driving line TDL31 may simultaneously connect the 3-1th channel CH31 of the pixel driving circuit PD and the fourth to sixth touch electrodes TE4 to TE6. The 3-2th touch driving line TDL32 may simultaneously connect the 3-2th channel CH32 of the pixel driving circuit PD and the fourth to sixth touch electrodes TE4 to TE6. The 3-3th touch driving line TDL33 may simultaneously connect the 3-3th channel CH33 of the pixel driving circuit PD and the fourth to sixth touch electrodes TE4 to TE6.

The 4-1th touch driving line TDL41 may simultaneously connect the 4-1th channel CH41 of the pixel driving circuit PD and the fourth to sixth touch electrodes TE4 to TE6. The 4-2th touch driving line TDL42 may simultaneously connect the 4-2th channel CH42 of the pixel driving circuit PD and the fourth to sixth touch electrodes TE4 to TE6. The 4-3th touch driving line TDL43 may simultaneously connect the 4-3th channel CH43 of the pixel driving circuit PD and the fourth to sixth touch electrodes TE4 to TE6.

That is, one touch electrode TE may be connected to the plurality of touch driving lines TDL. Accordingly, even if a defect occurs in any one touch driving line TDL, the touch electrode TE and the sensing block SB including the touch electrode TE may be normally driven. In addition, since the plurality of touch driving lines TDL are arranged in parallel, resistance between the plurality of touch driving lines TDL may be reduced.

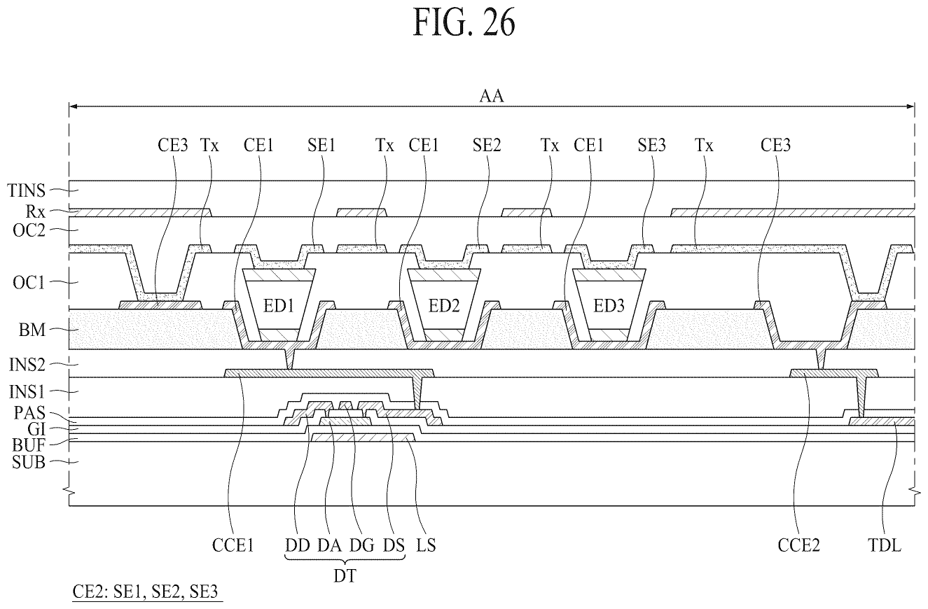

FIG. 26 is a cross-sectional view of a display device according to another embodiment of the present specification.

In FIGS. 1 to 25 described above, driving of a light emitting device and a touch electrode by a plurality of pixel driving circuits PD composed of a microchip or a chipset is disclosed. On the other hand, FIG. 26 illustrates driving of the light emitting device and the touch electrode by a plurality of transistors instead of the plurality of pixel driving circuits PD. In addition, FIG. 26 illustrates a touch electrode structure in the mutual-capacitance type.

A light shielding layer LS may be disposed on a substrate SUB. The light shielding layer LS may prevent a driving thin film transistor DT from being affected by external light.

The substrate SUB may be formed of glass or plastic, but the present disclosure is not limited thereto. The display device according to an embodiment of the present disclosure may be formed by a top emission method. Accordingly, the substrate SUB may be formed of an opaque material as well as a transparent material.

The light shielding layer LS may include a conductive material capable of blocking light. For example, the light shielding layer LS may be formed of an opaque metal material such as aluminum (Al), silver (Ag), copper (Cu), molybdenum (Mo), titanium (Ti), tungsten (W), or chromium (Cr), or an alloy thereof. FIG. 26 illustrates that the light shielding layer LS is formed as a single layer, but the present disclosure is not limited thereto. For example, the light shielding layer LS may be formed of multiple layers.

A buffer layer BUF may be disposed on the substrate SUB and may cover the light shielding layer LS. The buffer layer BUF may include silicon nitride (SiNx) or silicon oxide (SiOx). Although illustrated as a single layer, the buffer layer BUF may be formed of multiple layers. The buffer layer BUF may insulate the light shielding layer LS and may improve adhesion between layers formed on the buffer layer BUF and the substrate SUB.

A driving thin film transistor DT may be disposed on the buffer layer BUF. In addition, the driving thin film transistor DT may be disposed at a position overlapping the light shielding layer LS. Accordingly, since the light shielding layer LS is disposed under the driving thin film transistor DT, reliability of the driving thin film transistor DT may be improved by preventing external light from affecting the driving thin film transistor DT.

The driving transistor DT may include a semiconductor layer DA, a gate electrode DG, a source electrode DS, and a drain electrode DD.

The semiconductor layer DA may be disposed on the buffer layer BUF. The semiconductor layer DA may include a poly-silicon semiconductor or an oxide semiconductor. In addition, when the semiconductor layer DA includes an oxide semiconductor, the semiconductor layer DA includes at least one oxide of indium-gallium-zinc-oxide (IGZO), indium-gallium-tin-oxide (IGO), and indium-gallium-tin-oxide (IGO).

A gate insulating layer GI may be disposed between the semiconductor layer DA and the gate electrode DG. That is, the gate insulating layer GI may be disposed on the semiconductor layer DA, and the gate electrode DG may be disposed on the gate insulating layer GI. The semiconductor layer DA and the gate electrode DG may be insulated from each other by the gate insulating layer GI. The gate insulating layer GI may include silicon nitride (SiNx) or silicon oxide (SiOx). Although illustrated as a single layer, the gate insulating layer GI may be formed of multiple layers.

One side of the semiconductor layer DA may be electrically connected to the source electrode DS through a contact hole, and the other side of the semiconductor layer DA may be connected to the drain electrode DD through a contact hole. In addition, a touch driving line TDL may be disposed on the same layer as the source electrode DS and the drain electrode DD.

A passivation layer PAS may be disposed on the driving thin film transistor DT. The passivation layer PAS may protect the driving thin film transistor DT. The passivation layer PAS may include silicon nitride (SiNx) or silicon oxide (SiOx).

A first insulating layer INS1 may be disposed on the passivation layer PAS. The first insulating layer INS1 may planarize an upper portion of the driving thin film transistor DT. The first insulating layer INS1 may include an organic insulating material such as an acrylic resin, an epoxy resin, a phenolic resin, a polyamide resin, or a polyimide resin.

A first contact electrode CCE1 and a second contact electrode CCE2 may be disposed on the first insulating layer ISN1. The first contact electrode CCE1 and the second contact electrode CCE2 may be spaced apart from each other. The first contact electrode CCE1 may be connected to the driving thin film transistor DT through a contact hole. FIG. 26 shows that the first contact electrode CCE1 is connected to the source electrode DS, but the present disclosure is not limited thereto. For example, the first contact electrode CCE1 may be connected to the drain electrode DD. The second contact electrode CCE2 may be connected to the touch driving line TDL through a contact hole.

A second insulating layer INS2 is disposed on the first insulating layer INS1 and may cover the first contact electrode CCE1 and the second contact electrode CCE2. The second insulating layer INS2 may planarize upper portions of the first contact electrode CCE1 and the second contact electrode CCE2.

A black matrix BM and a plurality of light emitting devices ED may be disposed on the second insulating layer INS2. The plurality of light emitting devices ED may include a first light emitting device ED1, a second light emitting device ED2, and a third light emitting device ED3. Each of the first light emitting device ED1, the second light emitting device ED2, and the third light emitting device ED3 may be disposed in an area surrounded by the black matrix BM. In addition, the structure of each of the plurality of light emitting devices ED is the same as the structure of the light emitting device described above with reference to FIG. 11, and thus the description thereof will be omitted.

Each of the first light emitting device ED1, the second light emitting device ED2, and the third light emitting device ED3 may be connected to the first contact electrode CCE1 through a first electrode CE1. The first electrode CE1 may be disposed between the first light emitting device ED1 and the second insulating layer INS2, between the second light emitting device ED2 and the second insulating layer INS2, and between the third light emitting device ED3 and the second insulating layer INS2.

Since the first contact electrode CCE1 is connected to the driving thin film transistor DT, each of the first light emitting device ED1, the second light emitting device ED2, and the third light emitting device ED3 may be connected to the driving thin film transistor DT through the first electrode CE1 and the first contact electrode CCE1. In addition, FIG. 26 illustrates only that the first light emitting device ED1 is connected to the first contact electrode CCE1 through the first electrode CE1, but the second light emitting device ED2 and the third light emitting device ED3 may also have the same connection structure.

A first planarization layer OC1 may be disposed on the black matrix BM and the plurality of light emitting devices ED. The first planarization layer OC1 may fill a space between the black matrix BM and the plurality of light emitting devices ED. In addition, the first planarization layer OC1 may cover the black matrix BM. In addition, the first planarization layer OC1 may cover a portion of upper surfaces of each of the first light emitting device ED1, the second light emitting device ED2, and the third light emitting device ED3.

A second electrode CE2 and a Tx electrode Tx may be disposed on the first planarization layer OC1. In addition, the second electrode CE2 and the Tx electrode Tx may be spaced apart from each other on the first planarization layer OC1.

The second electrode CE2 may be disposed on the first light emitting device ED1, the second light emitting device ED2, and the third light emitting device ED3. As described in FIG. 14, the second electrode CE2 may include a first sub-electrode SE1, a second sub-electrode SE2 and a third sub-electrode SE3. The first sub-electrode SE1 may be in contact with a cathode of the first light emitting device ED1, the second sub-electrode SE2 may be in contact with a cathode of the second light emitting device ED2, and the third sub-electrode SE3 may be in contact with a cathode of the third light emitting device ED3. That is, each of the first sub-electrode SE1, the second sub-electrode SE2, and the third sub-electrode SE3 may be connected to a different light emitting device.

The Tx electrode Tx may be connected to the second contact electrode CCE2 through a third electrode CE3. The third electrode CE3 may be disposed in an area surrounded by the black matrix BM. Alternatively, the Tx electrode Tx may be disposed on the black matrix BM. The third electrode CE3 may be spaced apart from the first electrode CE1.

Since the second contact electrode CCE2 is connected to the touch driving line TDL, the Tx electrode Tx may be connected to the touch driving line TDL through the third electrode CE3 and the second contact electrode CCE2. In addition, FIG. 26 illustrates a structure in which the Tx electrode Tx and the touch driving line TDL are connected in a right region of the Tx electrode Tx, but the present disclosure is not limited thereto.

A partial area of the Tx electrode Tx may be disposed between the first sub-electrode SE1 and the second sub-electrode SE2, and another partial area of the Tx electrode Tx may be disposed between the second sub-electrode SE2 and the third sub-electrode SE3.

A second planarization layer OC2 may be disposed on the second electrode CE2 and the Tx electrode Tx. The second planarization layer OC2 may planarize upper portions of the second electrode CE2 and the Tx electrode Tx.

A Rx electrode Rx may be disposed on the second planarization layer OC2. The Rx electrode Rx may not overlap the light emitting device ED, but may overlap the Tx electrode Tx. That is, the Rx electrode Rx may be disposed between the light emitting device ED adjacent to each other.

A touch insulation layer TINS is disposed on the second planarization layer OC2 and may cover the Rx electrode Rx.

As described in FIG. 14, the present disclosure discloses the use of the metal layer disposed on the same layer as the second electrode CE2 as a Tx electrode Tx. Accordingly, only the Rx electrode Rx is additionally formed on the second electrode CE2, and a touch may be detected by using an insulating layer such as the second planarization layer OC2 provided between the second electrode CE2 and the Rx electrode Rx as a touch insulating layer.

In addition, by forming the second electrode CE2 to include the plurality of sub-electrodes SE, Tx electrodes Tx are additionally formed not only in the outer regions of the pixel PX but also in an area between the light emitting devices ED adjacent to each other. Accordingly, by increasing the number of Tx electrodes Tx and Rx electrodes Rx, an accuracy of touch detection may be improved.

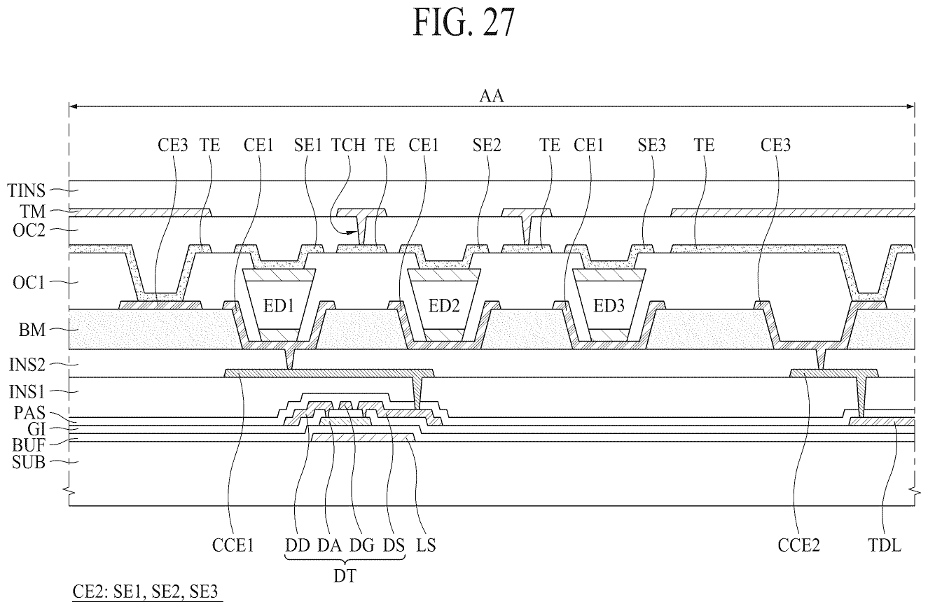

FIG. 27 is a cross-sectional view of a display device according to another embodiment of the present specification.

Like FIG. 26, FIG. 27 discloses driving light emitting devices and touch electrodes by a plurality of transistors instead of pixel driving circuits PD. In addition, FIG. 26 discloses a touch electrode structure in the mutual-capacitance type, while FIG. 27 discloses a touch electrode structure in the self-capacitance type.

In FIG. 26, the plurality of Tx electrodes Tx and the plurality of Rx electrodes Rx are disclosed, but in FIG. 27, a plurality of touch electrodes TE and a touch metal layer TM are disclosed. Referring to FIG. 27, the second electrode CE2 may be disposed on the first light emitting device ED1, the second light emitting device ED2, and the third light emitting device ED3. As described in FIG. 14, the second electrode CE2 may include a first sub-electrode SE1, a second sub-electrode SE2 and a third sub-electrode SE3. The first sub-electrode SE1 is in contact with the cathode of the first light emitting device ED1, the second sub-electrode SE2 is in contact with the cathode of the second light emitting device ED2, and the third sub-electrode SE3 may be in contact with the cathode of the third light emitting device ED3. That is, each of the first sub-electrode SE1, the second sub-electrode SE2, and the third sub-electrode SE3 may be connected to a different light emitting device.

The touch electrode TE may be connected to the second contact electrode CCE2 through the third electrode CE3. The touch electrode TE may be disposed in an area surrounded by the black matrix BM. Alternatively, the touch electrode TE may disposed provided on the black matrix BM. The third electrode CE3 may be spaced apart from the first electrode CE1.

A partial area of the touch electrode TE may be disposed between the first sub-electrode SE1 and the second sub-electrode SE2, and another partial area of the touch electrode TE may be disposed between the second sub-electrode SE2 and the third sub-electrode SE3.

The second planarization layer OC2 may be disposed on the second electrode CE2 and the touch electrode TE. The second planarization layer OC2 may planarize the upper portions of the second electrode CE2 and the touch electrode TE.

A touch metal layer TM may be disposed on the second planarization layer OC2. The touch metal layer TM may not to overlap the light emitting device ED and may overlap the touch electrode TE. That is, the touch metal layer TM may be disposed between the light emitting devices ED adjacent to each other.

The touch metal layer TM may be electrically connected to the touch electrode TE through a touch contact hole TCH. The touch contact hole TCH may penetrate the second planarization layer OC2. FIG. 27 illustrates that the touch contact hole TCH is disposed in an area between the first light emitting device ED1 and the second light emitting device ED2 and an area between the second light emitting device ED2 and third light emitting device ED3, but the present disclosure is not limited thereto.

Generally, the touch panel in the self-capacitance type discloses a touch electrode, a wiring layer for configuring a sensing block, and a touch insulating layer disposed between the touch electrode and the wiring layer. However, the present disclosure discloses using a metal layer disposed on the same layer as the second electrode CE2 and disposed in an outer area of the pixel PX and an area between the light emitting devices ED adjacent to each other as a touch electrode TE. Accordingly, only the touch metal layer TM may be additionally formed on the second electrode CE2 to detect a touch. Therefore, it is possible to reduce a thickness of the display device and simplify manufacture process.

In FIG. 27, the metal layer disposed on the same layer as the second electrode CE2 and disposed in an outer area of the pixel PX and an area between the light emitting devices ED adjacent to each other is used as the touch electrode TE, and the touch metal layer TM is formed on the touch electrode TE, but the present disclosure is not limited thereto. For example, a metal layer disposed on the same layer as the second electrode CE2 and disposed in an outer area of the pixel PX and an area between the light emitting devices ED adjacent to each other may be used as the touch metal layer TM, and the touch electrode TE may be formed on the touch metal layer TM.

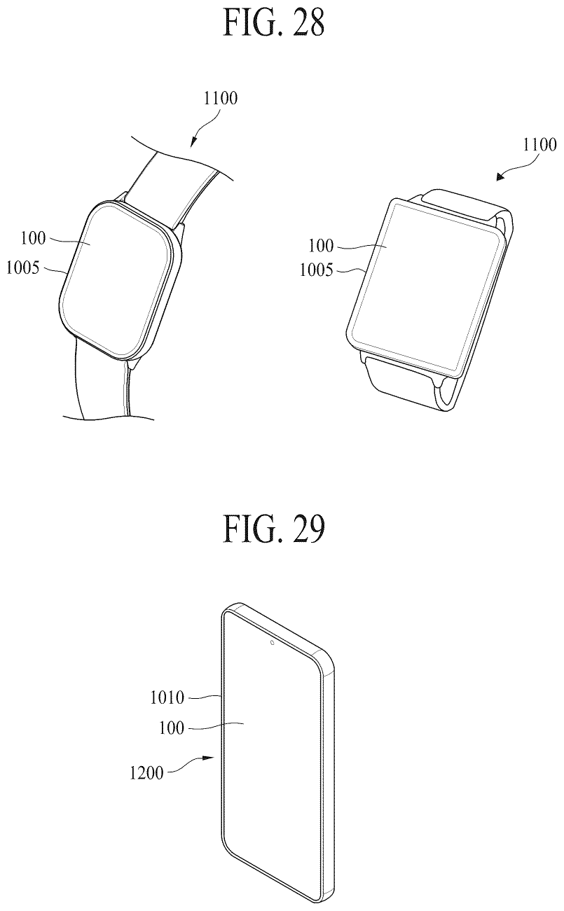

FIGS. 28 to 31 are diagrams illustrating devices to which a display device according to embodiments of the present disclosure is applied.

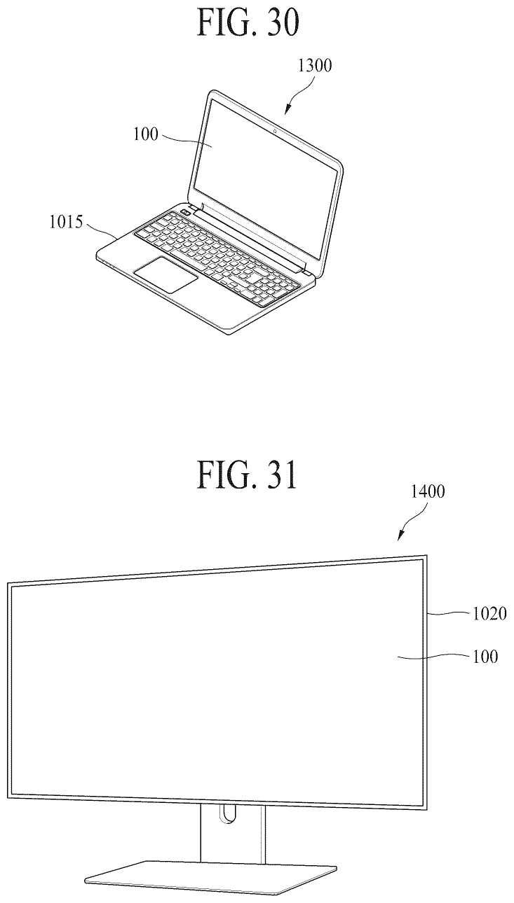

Referring to FIGS. 28 to 31, the display device according to embodiments of the present disclosure may be included in various devices or electronic devices. For example, various electronic devices may include a wearable device 1100 as shown in FIG. 28, a mobile device 1200 as shown in FIG. 29, a laptop 1300 as shown in FIG. 30, and a monitor or TV 1400 as shown in FIG. 31, but embodiments of the present disclosure are not limited thereto.

Each of the wearable device 1100, the mobile device 1200, the laptop 1300, and the monitor or TV 1400 may include a case unit 1005, 1010, 1015, and 1020 and a display panel 100 and a display device 1000 according to the above-described embodiments of the present disclosure.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

1. A display device comprising:
a plurality of pixels on a substrate;
a first sub-pixel and a second sub-pixel in the plurality of pixels and spaced apart from each other;
a first light emitting device in the first sub-pixel;
a second light emitting device in the second sub-pixel;
a plurality of banks disposed in each of the first sub-pixel and the second sub-pixel; and
a cathode and a first touch electrode on the first light emitting device and the second light emitting device;
wherein the cathode and the first touch electrode are on a same layer and are spaced apart from each other,
wherein the first light emitting device and the second light emitting device are micro light emitting diodes, and
wherein the first light emitting device and the second light emitting device are disposed on the plurality of banks.

2. The display device of claim 1, wherein the cathode overlaps the first light emitting device and the second light emitting device and the first touch electrode is non-overlapping with the first light emitting device and the second light emitting device.

3. The display device of claim 2,
wherein the cathode includes a first sub-electrode and a second sub-electrode spaced apart from each other,
wherein the first sub-electrode covers the first light emitting device and the second sub-electrode covers the second light emitting device.

4. The display device of claim 3, wherein the first touch electrode is between the first light emitting device and the second light emitting device.

5. The display device of claim 1, further comprising:
a black matrix on the cathode and the first touch electrode,
wherein the black matrix is between the first light emitting device and the second light emitting device, and the black matrix overlaps the first touch electrode.

6. The display device of claim 5, further comprising:
a second touch electrode on the black matrix, the second touch electrode overlapping the first touch electrode.

7. The display device of claim 6, wherein the black matrix further includes a touch contact hole,
wherein the first touch electrode is electrically connected to the second touch electrode through the touch contact hole.

8. The display device of claim 1, further comprising:
a pixel driving circuit on the substrate; and
a touch driving line on the pixel driving circuit,
wherein the pixel driving circuit applies a touch driving signal to the first touch electrode through the touch driving line.

9. The display device of claim 8, wherein the first touch electrode includes a 1-1th touch electrode and a 1-2th touch electrode spaced apart from each other, and
wherein the pixel driving circuit applies a same touch driving signal to the 1-1th touch electrode and the 1-2th touch electrode.

10. The display device of claim 9, wherein the touch driving line includes a first touch driving line connected to a first channel of the pixel driving circuit and a second touch driving line connected to a second channel of the pixel driving circuit,
wherein the 1-1th touch electrode is connected to the first touch driving line and the 1-2th touch electrode is connected to the second touch driving line.

11. The display device of claim 9, wherein the touch driving line includes a first touch driving line connected to a first channel of the pixel driving circuit, and the 1-1th touch electrode and the 1-2th touch electrode are connected to the first touch driving line.

12. The display device of claim 9, wherein the touch driving line includes a first touch driving line connected to a first channel of the pixel driving circuit and a second touch driving line connected to a second channel of the pixel driving circuit,
wherein the 1-1th touch electrode is connected to the first touch driving line and the second touch driving line, and the 1-2th touch electrode is connected to the first touch driving line and the second touch driving line.

13. The display device of claim 1, wherein the first touch electrode includes a plurality of opening areas overlapping each of the plurality of pixels,
wherein the plurality of opening areas include a first opening area and a second opening area spaced apart from the first opening area, and
wherein the cathode includes a first cathode in the first opening area and a second cathode in the second opening area.

14. The display device of claim 13, wherein the first opening area includes a 1-1th opening area and a 1-2th opening area spaced apart from the 1-1th opening area,
wherein the first cathode includes a first sub-electrode in the 1-1th opening area and a second sub-electrode in the 1-2th opening area,
wherein the first sub-electrode overlaps the first light emitting device and the second sub-electrode overlaps the second light emitting device.

15. The display device of claim 14, wherein the first touch electrode is between the 1-1th opening area and the 1-2th opening area.
